(19) United States
(12) Patent Application Publication
(10) Pub. No.: US 2021/0225803 A1
(43) Pub. Date: Jul. 22, 2021

(54) COVALENTLY BONDED SEMICONDUCTOR INTERFACES

(71) Applicant: G-ray Industries SA, Hauterive (CH)

(72) Inventors: Hans VON KÄNEL, Wallisellen (CH); Franco BRESSAN, Pombino Dese - Padova (IT)

(73) Assignee: G-ray Industries SA, Hauterive (CH)

(21) Appl. No.: 17/254,316

(22) PCT Filed: Jun. 24, 2019
(86) PCT No.: PCT/IB2019/055293

§ 371 Date: Dec. 21, 2020

Related U.S. Application Data
(60) Provisional application No. 62/688,420, filed on Jun. 22, 2018.

(51) Int. Cl. H01L 23/00

(52) U.S. Cl. CPC H01L 24/83; H01L 24/75; H01L 2224/8312; H01L 2224/75983; H01L 2224/83011; H01L 2224/75102

(57) ABSTRACT

Production system for wafer bonding comprising modules for wet chemical wafer cleaning and surface passivation and vacuum modules with base pressure in the ultrahigh vacuum regime for the removal of surface passivation, wafer flipping and alignment, low temperature annealing and wafer bonding, with all modules integrated in the same tool and individually serviceable. Methods for oxide-free covalent semiconductor wafer bonding include wet chemistry and vacuum processing at low temperatures compatible with CMOS processed wafers.

### CROSS REFERENCE TO RELATED APPLICATIONS

This application claims priority to and benefit of U.S. Provisional Application No. 62/688,420 filed 22 Jun. 2019, which is incorporated herein by reference and relied upon.

### COPYRIGHT & LEGAL NOTICE

A portion of the disclosure of this patent document contains material which is subject to copyright protection. The Applicant has no objection to the facsimile reproduction by anyone of the patent document or the patent disclosure as it appears in the Patent and Trademark Office patent file or records, but otherwise reserves all copyright rights whatsoever. Further, no references to third party patents or articles made herein is to be construed as an admission that the present invention is not entitled to antedate such material by virtue of prior invention.

### FIELD OF THE INVENTION

The invention relates to an industrial system for forming covalently bonded semiconductor interfaces, the structure of covalently bonded semiconductor interfaces, and to methods for forming such interfaces at CMOS compatible temperatures.

### BACKGROUND OF THE INVENTION

The formation of an electrically conductive, covalent bond formed between two semiconductor wafers has met increasing interest in the past few decades. Especially covalent semiconductor bonding carried out at low temperatures (typically between room temperature and about 300° C.) may lead to monolithic structures which cannot be realized in any other way, since often the bonding partners comprise materials which do not allow any high temperature processing. This is the case, for example, for CMOS processed wafers containing a temperature sensitive stack of dielectric and metallic layers, or wafers made of materials with different thermal expansion coefficients and/or lattice parameters. Low bonding temperatures alone do not guarantee unimpaired electrical conduction across a bonding interface. In addition, the surfaces of both bonding partners must typically be atomically clean and oxide-free as well as smooth and flat. Clean silicon wafers have been shown to be spontaneously bondable at room temperature in a UHV (Ultra High Vacuum, defined hereinafter) bonding tool suitable for 100 mm wafer processing with bonds approaching bulk bond strength (see, for example, U. Gösele et al. in Appl. Phys. Lett. 67, 3614 (1995), the entire disclosure of which is hereby incorporated by reference). The question then is how to obtain clean semiconductor surfaces prior to low temperature bonding and how to keep them clean before the covalent bond is formed. This remains a serious issue, especially for materials which oxidize as easily as silicon. One way to obtain oxide-free silicon surfaces is wet chemical cleaning in the form of an HF dip. The resulting hydrogen termination passivates the surface and protects it from re-oxidation even in ambient atmosphere up to several hours. The hydrogen passivation needs to be removed before bonding, because hydrophobic bonding by means of hydrogen bridges is weak and therefore requires undesirable post-bonding annealing to temperatures above 700° C. to achieve high bond strength (see, for example, Q.-Y. Tong et al. in Appl. Phys. Lett. 64, 625 (1994), the entire disclosure of which is hereby incorporated by reference). Hydrogen can be removed from passivated surfaces by thermal annealing in ultra-high vacuum (UHV—attaining a base pressure in the range of about 1×10⁻⁹ to 1×10⁻¹⁰ mbar or even 10⁻¹⁰ to 10⁻¹¹ mbar). This is the method used by Gösele et al. for Si—Si bonding, which, however, has the disadvantage of requiring temperatures above the monohydride desorption temperature of about 550° C. (see, for example, P. Gupta et al., in Phys. Rev. B 37, 8234 (1988) and U. Gösele et al. in Appl. Phys. Lett. 67, 3614 (1995), the entire disclosures of which are hereby incorporated by reference). Unfortunately, this is not compatible with fully CMOS processed wafers which require not only low temperatures during bonding but also in any pre-bonding cleaning step.

A possible way of removing surface oxides at low temperatures is the so-called surface activation method. It was originally introduced for Al—Al bonding by T. Suga et al. in Acta metall. mater. 40, 5133 (1992), the entire disclosure of which is hereby incorporated by reference. The method, essentially consisting of dry etching of the oxide by ion beam sputtering with ion energies on the order of 1 keV, was later shown to be applicable also to Si—Si bonding by Takagi et al. who coined the expression Surface Activated Bonding (SAB) (see, for example, H. Takagi et al. in Appl. Phys. Lett. 68, 2222 (1996), the entire disclosure of which is hereby incorporated by reference). Exceptionally high bond strength was achieved by the SAB method even for room temperature bonding. Dry etching of the oxide has, however, one drawback which is hard to avoid irrespective of the details of the parameters used. Surface bombardment by energetic ions inevitably causes surface damage during oxide removal, leading to an amorphous interlayer at the bonding interface with a thickness typically on the order of a few nanometres (see for example Takagi et al., in ECS Transactions 75, 3 (2016), the entire disclosure of which is hereby incorporated by reference). The high dangling bond density associated with the broken Si—Si bonds pins the Fermi level in the energy gap. The dangling bond density may be reduced by recrystallizing the amorphous layer, which, however, requires again annealing at temperatures typically above 500° C. Depending on the doping type and density of the bonding partners Fermi level pinning at the bonding interface may result in similar band bending and barrier formation as can be found at polycrystalline grain boundaries, with similar effects on the electrical properties. Especially for low doping densities, characterized by wide space charge regions through which tunnelling is impossible, the electrical resistance across such a bonding interface may exceed the bulk resistance by many orders of magnitude (see, for example, A. Jung et al. in J. Appl. Phys. 123, 085701 (2018), the entire disclosure of which is hereby incorporated by reference). Evidently, bonding of clean, crystalline surfaces in UHV may provide the lowest possible density of interface defect states, although, except for extremely accurate wafer alignment (both in terms of twist and tilt), barrier formation may not be prevented even in this case (see for example A. Reznicek et al. in MRS Symp. Proc. 681E, I4.4.1 (2001), the entire disclosure of which is hereby incorporated by reference).

A UHV bonding system for 200 mm wafers, based on SAB and comprising very accurate wafer alignment features, was introduced already in 2001 by Suga et al. at the 2001 Electronic Components and Technology Conference, the entire disclosure of which is hereby incorporated by reference. The wafer alignment up to a precision of ±0.5 μm, including maintaining parallelism between wafers, is established by means of piezo-actuators and infrared cameras, which is why the technique is limited to the bonding of infrared transparent wafers. While very suitable for the packaging of micro-electronic mechanical systems (MEMS), the amorphous semiconductor interfaces produced by this system are of major concern for the electric charge transport for the reasons explained above.

Similar drawbacks in terms of interfacial electric transport appear to exist for a high vacuum production tool introduced by EV Group but a few years ago (see for example, U.S. Pat. No. 9,899,223 to Wimplinger et al., the entire disclosure of which is hereby incorporated by reference). The reason is that here too dry etching of SiO₂ by energetic ion bombardment results in amorphous interlayers several nanometres in width (see for example C. Flötgen et al., in ECS Transactions 64, 103 (2014), the entire disclosure of which is hereby incorporated by reference).

There is a need for a production system for covalent bonding of semiconductor wafers in ultrahigh vacuum up to 300 mm in size.

There is a need for a production system for covalent bonding of semiconductor wafers in ultrahigh vacuum comprising mutual wafer alignment at a 100 nm scale.

There is a need for a production system and process for covalent semiconductor wafer bonding which permits smooth, crystalline wafer surfaces to be created and maintained oxide-free for a length of time sufficient to carry out the bonding process under production conditions.

There is a need far a production system and process for covalent semiconductor wafer bonding which permits oxide removal and surface passivation without inducing surface amorphization.

There is a need for a production system and process for covalent semiconductor wafer bonding which permits the removal of passivating layers on wafers without inducing surface amorphization.

There is a need for a production system and process for covalent semiconductor wafer bonding which permits oxide-free, electrically conducting bonding interfaces to be created under production conditions.

There is a need for a production system and process permitting covalent semiconductor wafer bonding at temperatures compatible with CMOS processed wafer stacks.

There is a need for a production system and process for the covalent bonding of semiconductor wafers with different thermal expansion coefficients.

There is a need for a production system and process for covalent wafer bonding capable of providing bonding interfaces with defect densities low enough to ensure minimal interfacial barrier formation.

### SUMMARY OF THE INVENTION

A production system for oxide-free, covalent semiconductor wafer bonding is provided. The system includes at least one module for wet chemical or vapour processing and at least one module for ultra-high vacuum (UHV) wafer processing. The module for wet chemical or vapour processing has chambers for oxide removal and for the provision of a surface passivation layer at or near atmospheric pressure. The module for ultra-high vacuum wafer processing includes at least one chamber. This chamber may be any one of the following: (i) a plasma chamber with a low energy plasma source and auxiliary laser irradiation suitable for the removal of surface passivation, (ii) an ultrahigh vacuum laser chamber with a visible or ultraviolet laser suitable for the photochemical or photo-thermal removal of a surface passivation layer, (iii) an ultrahigh vacuum thin film deposition chamber suitable for the provision of a thin, clean epitaxial semiconductor surface layer, (iv) an ultrahigh vacuum wafer flipping chamber, (v) an ultrahigh vacuum wafer annealing chamber, (vi) an ultrahigh vacuum wafer pre-alignment tool, and (v) an ultrahigh vacuum wafer bonding chamber comprising means for mutual wafer alignment at ultrahigh rotational and translational accuracy, the bonding chamber being optionally vibrationally decoupled from a wafer handling chamber. The modules for wet chemical and the modules for ultra-high vacuum processing are accessible through separate load-locks and are connected by at least one buffer chamber designed to avoid cross contamination during wafer transfer by robots in wafer handlers.

It is an object of the invention to provide a production system and process for the covalent, oxide- and particle-free bonding of semiconductor wafers up to 300 mm in size.

It is an object of the invention to provide a production system for the covalent, oxide- and particle-free bonding of semiconductor wafers up to 300 mm in size, mutually aligned with a precision in the 100 nm range.

It is an object of the invention to provide a production system and process for covalent wafer bonding for semiconductors with different thermal expansion coefficients.

It is an object of the invention to provide a production system and process for covalent, oxide-free semiconductor wafer bonding which combines modules for wet chemical wafer processing and modules for vacuum based wafer processing in a single machine.

It is an object of the invention to provide a production system and process for covalent semiconductor wafer bonding comprising an ultra-high vacuum (UHV) compatible environment to keep all clean wafer surfaces oxide-free.

It is an object of the invention to provide a production system and process for covalent semiconductor wafer bonding capable of providing clean, low-roughness wafer surfaces suitable for wafer bonding at CMOS compatible temperatures.

It is an object of the invention to provide a production system and process for covalent semiconductor wafer bonding capable of providing crystalline bonding interfaces at CMOS compatible temperatures.

It is an object of the invention to provide a production system and process for covalent semiconductor wafer bonding capable of providing bonding interfaces at CMOS compatible temperatures with minimal undesired electrical barrier formation by interfacial defect states.

It is an object of the invention to provide a production system and process for covalent semiconductor wafer bonding capable of providing bonding interfaces at CMOS compatible temperatures with minimal undesired electrical charge trapping and recombination at the bonding interface.

It is an object of the invention to provide a production system for covalent semiconductor wafer bonding of a modular design which is easy to service and maintain particle-free.

### BRIEF DESCRIPTION OF THE DRAWINGS

FIG. 1 is a schematic view of a production system for covalent semiconductor wafer bonding comprising sections for wet chemical and UHV compatible wafer processing.

FIG. 2 is a schematic view of a production system for covalent semiconductor wafer bonding comprising sections for wet chemical and UHV compatible wafer processing, both equipped with central wafer handlers.

FIG. 3 is a schematic view of a production system for covalent semiconductor wafer bonding comprising separate sections for wet chemical and UHV compatible wafer processing communicating by UHV wafer suitcases or docking stations

FIG. 4A is a perspective view of a bonding chamber comprising actuators and sensors for ultra-precise mutual wafer alignment.

FIG. 4B is a top view of a bonding chamber with actuators and sensors for the parallel alignment of wafers.

FIG. 4C is a bottom view of a bonding chamber with actuators and confocal interferometric sensors for accurate rotational and translational wafer alignment.

FIG. 4D is a perspective view of the lower part of a bonding chamber with confocal interferometric sensors for ultra-precise rotational and translational wafer alignment.

FIG. 4E is a view of upper and bottom wafer with alignment features before and after accurate alignment by confocal interferometric sensors.

FIG. 5 is a perspective view of a plasma chamber with a heatable wafer stage and remote laser surface heating.

FIG. 6 is a schematic view of a process sequence for oxide-free, covalent semiconductor wafer bonding comprising steps of wet chemical oxide etching and plasma processing.

FIG. 7 is a schematic view of a process sequence for oxide-free, covalent semiconductor wafer bonding comprising steps of wet chemical oxide etching and epitaxial growth.

FIG. 8 is a schematic view of a process sequence for ultra-high accuracy alignment of wafers in the bonding chamber.

### DETAILED DESCRIPTION OF THE PREFERRED EMBODIMENTS

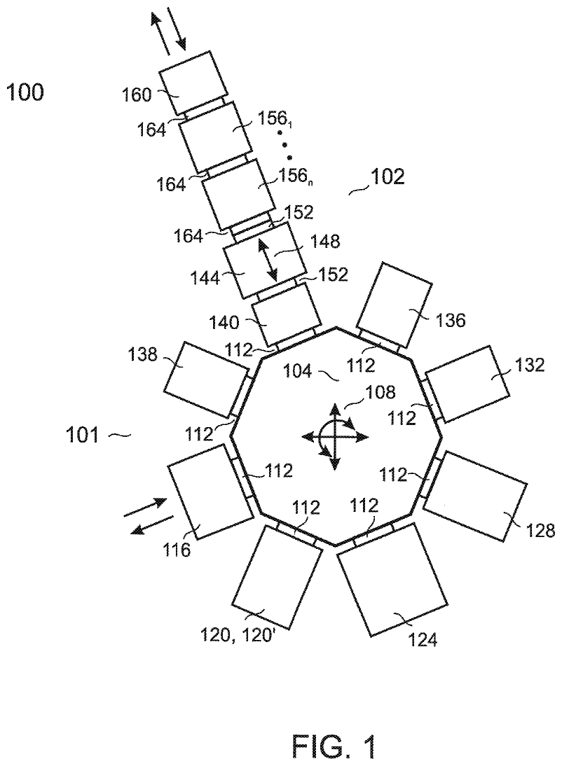

Referring now to FIG. 1, first embodiment 100 of a production system for low-temperature covalent bonding of semiconductor wafers up to 300 mm in size is made up of two connected parts 101,102. A first part 101 is a vacuum system with modules all of which are compatible with ultra-high vacuum processing. The second part 102 is a system operating essentially at atmospheric pressure with modules designed for wet chemical or vapour processing. Both parts are accessible by separate load locks 116, 160 and connected through a buffer chamber 140 the purpose of which is to avoid cross-contamination.

The first part 101 of the production system 100 for low-temperature covalent wafer bonding under UHV-compatible processing conditions comprises a central wafer handler 104 with a robot 108 capable of serving a multitude of processing chambers attached via UHV compatible gate valves 112. For average sized process chambers UHV of about (2−5)×10⁻¹⁰ mbar is attainable for example using a combination of a turbo-molecular vacuum pump available from Pfeiffer/Edwards and an Edwards scroll dry backing pump after baking for 24 h at 150° C. For example, with Ti sublimation pumps, cryopumps or ion getter pumps even lower pressures in the range of 10⁻¹⁰-10⁻¹¹ mbar may be achieved. Central wafer handler 104 may be “bakeable” preferably to a temperature of about 150°-200° C. to remove moisture and to permit pumping to a base pressure of about 10⁻⁸ mbar or 10⁻⁸−5×10⁻⁹ mbar or even 5×10⁻⁹-10⁻¹⁰ mbar, for example, by a combination of turbomolecular and cryopumps. The production system comprises at least one load lock 116 for the insertion of wafer cassettes, equipped with vacuum pumps for evacuation to about 10⁻⁶-10⁻⁷ mbar or even less than 10⁻⁷ mbar. The at least one load lock 116 may optionally be equipped with provisions for wafer degassing, for example, at temperatures in the range of 100°-200° C. The production system 100 may further comprise one or several process chambers 120, 120′ with base pressures in the UHV range, dedicated to the removal of the surface passivation of wafers to expose clean semiconductor surfaces with reactive dangling bonds suitable for covalent semiconductor bonding. One process chamber 120′ may, for example, be a UHV laser processing chamber equipped for visible or UV laser exposure of the surfaces, the laser providing photon energies in a range of about 2-10 eV, permitting for example, either photochemical or photo-thermal hydrogen desorption from Si or other hydrogen passivated semiconductor surfaces (see, for example, A. Pusel et al., in Phys. Rev. Lett. 81, 645 (1998), the entire disclosure of which is hereby incorporated by reference). Laser processing chamber 120′ may be equipped with a rotatable wafer stage and with an auxiliary heater for uniform heating of the back of a wafer. The control of the wafer surface temperature may be provided by an infrared temperature sensor. The sensor may be mounted on a tilt module, permitting infrared radiation emitted from any point between the center and edge of the wafer to be measured. A feedback loop between the sensor and the rotation speed of the wafer stage and the power supplied to the laser may provide real time control of the surface temperature at any location on the wafer.

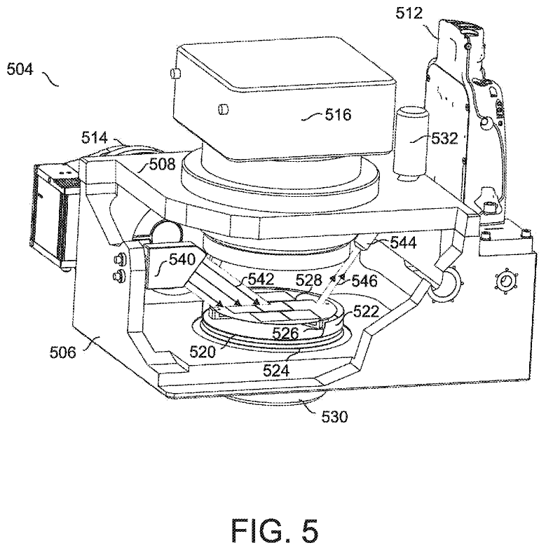

Alternatively, a process chamber may be equipped with a low energy plasma source. As an exemplary example we consider plasma chamber 120 equipped with vacuum pumps capable of providing a UHV base pressure in the range of 5×10⁻⁹-5×10⁻¹⁰ mbar or even 5×10⁻¹⁰-5×10⁻¹¹ mbar (see also more detailed embodiment 500 of FIG. 5). The plasma chamber 120 hosts a low-energy plasma source providing ion energies below the sputter threshold of most solid materials, for example, about 10-15 eV, The plasma source may, for example, be an inductively coupled plasma source such as, for example, the Copra DN250 CF plasma source from CCR Technology (ccrtechnology.de/products.php) which can be operated with different discharge gases, such as N₂, He, Ar, Ne, Kr or mixtures thereof. Plasma chamber 120 may host any plasma source capable of providing low energy ions in the range of about 10-20 eV or even 5-10 eV. The gas lines supplying the low-energy plasma source are preferably all equipped with sorption filters removing traces of water and oxygen, along with particle filters known in the art. Plasma chamber 120 is further equipped with a rotatable wafer stage which may optionally be heated to temperatures of about 100°-300° C. The combination of a low energy plasma source with a heatable wafer stage offers the possibility to remove, for example, the hydrogen coverage of H-passivated semiconductor surfaces without inducing any substantial surface amorphization or implantation of gas particles during the plasma treatment process. As an alternative or in addition to a heatable wafer stage plasma chamber 120 may be equipped for laser heating of the wafer surface. Laser heating may for example be realized by an of array laser diodes with emission wavelengths from visible to UV, providing just local surface heating as result of appropriately chosen wavelengths for small penetration depth. Laser exposure of the entire wafer surface is thereby guaranteed by the rotating wafer stage. Intense UV lasers may in addition ionize or promote the atoms of rare gases introduced into chamber 120 to a highly excited state, the energy of which, when transferred to the surface, may further enhance the release of adsorbed hydrogen. In an aspect of the embodiment chambers 120 for plasma processing and chamber 120′ for laser processing may both be present as separate chambers attached to central wafer handler 104, providing more flexibility for example for the removal of the hydrogen passivation on different semiconductor surfaces.

Part 101 of the production system 100 for low-temperature covalent wafer bonding comprises further at least one UHV bonding chamber 124 with a base pressure in the range of 5×10⁻⁹-5×10⁻¹⁰ mbar. Preferably, the entire bonding chamber is temperature controlled within about 0.5°-1° C., or preferably within 0.1°-0.5° C., or even more preferably within 0.05°-0.1° C. Bonding chamber 124 may optionally be equipped with a wafer alignment system which permits the wafer pair to be mutually aligned with a precision of, for example, 50-200 nm prior to bonding. Bonding chamber 124 may be vibrationally decoupled by a bellows from wafer handler 104 to facilitate accurate wafer alignment. The wafer alignment system may, for example, comprise an optical vision control system based on confocal interferometric sensors, and a precision translation and rotation mechanical stage driven for example by stepper motors or piezo motors for translational and rotational fine positioning.

Embodiment 400 of a bonding chamber equipped with an ultra-precise wafer alignment system which is easily scalable to the bonding of 300 mm wafers will be introduced further below. Optionally, the bonding chucks holding the wafers may be heatable to a temperature of about 100°-300° C. Wafer bonding is, however, preferably carried out at room temperature at bonding pressures ranging between about 0 and 200 kN. Bonded wafers may instead optionally be annealed in UHV annealing chamber 128, which may offer batch annealing at temperatures in the range of 100°-400° C. Alternatively, annealing chamber 128 may be equipped for single wafer annealing up to a maximum temperature of about 900° C. Single wafer annealing may be used for example for the hydrogen desorption from semiconductor wafers which do not present any thermal budget problem, such as passivated Si or Ge wafers for which complete thermal H-desorption requires temperatures of at most 600° C. and 400° C., respectively.

Part 101 of the production system 100 for low-temperature covalent wafer bonding may further comprise wafer alignment UHV chamber 132 for wafer pre-alignment with a base pressure in the range of 5×10⁻⁹-5×10⁻¹⁰ mbar or even 5×10⁻¹⁰-5×10⁻¹¹ mbar. Therein wafers may be pre-aligned rotationally to within a precision of about 0.1-0.5°, and translationally to within about 50-200 μm. Unless small features on the bonding partners need to be aligned, this pre-alignment may be sufficiently accurate for most applications of covalent bonding. Optionally, the pre-alignment of wafers may be carried out in handler 104 instead of a separate UHV chamber 132.

Furthermore, part 101 of the production system 100 for low-temperature covalent wafer bonding is equipped with UHV flipping chamber 136 pumped to a base pressure in the range of 5×10⁻⁹-5×10⁻¹⁰ mbar or even 5×10⁻¹⁰-5×10⁻¹¹ mbar. Wafer flipping in chamber 136 may be required to bring the wafer surfaces to be bonded face-to-face in bonding chamber 124.

Finally, part 101 of the production system 100 for low-temperature covalent semiconductor wafer bonding may optionally comprise UHV chamber 138 with a base pressure in the range of about 5×10⁻⁹ to 5×10⁻¹⁰ mbar or even 5×10⁻¹⁰ to 5×10⁻¹¹ mbar which may be equipped with means for thin film deposition for example of hydrogen passivated surfaces at substrate temperatures between room temperature and about 800° C. For temperature sensitive substrates, such as processed CMOS wafers, the slow deposition of very thin epitaxial semiconductor films a few monolayers in thickness at substrate temperatures between room temperature and about 300° C. may be an alternative way of preparing smooth, hydrogen-free crystalline surfaces suitable for covalent wafer bonding, provided that the chemical bond between the film material and hydrogen is weaker than the Si—H bond. Chamber 138 may, for example, be equipped with an optionally rotatable substrate holder in addition to a substrate heater and gas lines and mass flow controllers along with a low energy plasma source providing ion energies in the range of about 10-20 eV or even 5-10 eV, suitable for plasma assisted chemical vapour deposition for the epitaxial growth for example of 1-4 monolayers of Ge onto hydrogen terminated Si surfaces at very low temperatures, for example, between 150° and 300° C. and very low rates of, for example, 5-20 monolayers (ML) per minute or even 0.1 to 5 ML per minute. Alternatively, chamber 138 may be equipped with evaporators, such as electron beam evaporators or effusion cells, for example for the epitaxial deposition of a thin film of Ge or other semiconductor at similarly low rates. Slow epitaxial growth in UHV between room temperature and about 150°-300° C. may in fact be advantageous because it permits faster wafer transfer because there is no need for pumping down to UHV in contrast to a gas phase based technique. Furthermore, deposition rates can easily be controlled with great accuracy as they are independent of the substrate temperature, permitting accurate tailoring of layer thicknesses in the monolayer regime. Low deposition rates are desirable (or even necessary) in order to allow hydrogen to segregate from the passivated Si substrate surface to the surface of the growing Ge film (see, for example, T. Fujino et al., in Jpn. J. Appl. Phys. 40, L1173 (2001), the entire disclosure of which is hereby incorporated by reference). When the thickness of Ge films is kept below 4 ML, only a two-dimensional coherently strained (i.e. a layer the lattice parameter of which parallel to the interface is equal to the Si lattice parameter) wetting layer is formed and the nucleation of islands by means of the Stranski-Krastanow mechanism is suppressed (see, for example, M. Tomitori et al., in Appl. Surf. Sci. 76/77, 322 (1994), the entire disclosure of which is hereby incorporated by reference). Since hydrogen desorbs from Ge surfaces at about 300° C., a hydrogen-free Ge surface can be obtained at CMOS compatible temperatures in UITV (see, for example, D. Dick et al., in J. Phys. Chem. C 118, 482 (2014), the entire disclosure of which is hereby incorporated by reference). Alternatively, a short exposure to a low energy plasma or to laser irradiation near room temperature in plasma chamber 120 may be sufficient to provide a hydrogen-free, crystalline Ge surface. The invention therefore permits, for example, two Si wafers to be covalently bonded without the need of any surface bombardment by energetic particles by forming a Ge—Ge bond between two very thin Ge films epitaxially grown on the silicon wafers, for example, in UHV. Because the resulting Ge interfacial layer has a thickness of at most about one nanometre, corresponding to about 8 ML of Ge, or even substantially less, electrons can easily tunnel through. An ultrathin, coherently strained epitaxial Ge interlayer therefore does not contribute any significant resistance to the charge carrier transport across the bonding interface. The bonding of two Ge-terminated Si wafers instead of direct Si-to-Si bonding has the further advantage of a lower interfacial defect density because the higher mobility of Ge atoms is expected to lead to atomic reordering at the bonding interface at lower temperatures compared to Si interfaces. Hence the regular dislocation network due to wafer twist and tilt formed for Si interfaces only at annealing temperatures above about 800° C. (see for example T. Akatsu et al. in J. Mater. Sci. 39, 3031 (2004) and A. Reznicek et al. in MRS Symp. Proc. 681E, I4.4.1 (2001), the entire disclosures of which are hereby incorporated by reference) is expected to be present at Ge interfaces already in the as-bonded state or after annealing at temperatures as low as about 300° C. (see for example S. Ke et al. in J. Phys. D: Appl. Phys. 51, 265306 (2018), the entire disclosure of which is hereby incorporated by reference).That does not mean of course that the dislocation network at the bonding interface does not affect the electrical transport, but by keeping wafer twist and tilt small the dislocation density can be minimized.

The use of an epitaxial Ge interlayer is not limited to Si—Si bonding, but can easily be applied to the bonding of other materials with similar beneficial effects. One example is GaAs to Si bonding, which furthermore has the advantage of lattice matching between Ge and GaAs, as a result of which a Ge epitaxial layer on GaAs is defect free irrespective of its thickness. As an alternative to the slow epitaxial growth of an ultrathin Ge layer, another, preferably lattice-matched semiconductor layer may be epitaxially grown in chamber 138, fulfilling for example the same task of exchanging hydrogen-semiconductor bonds with semiconductor-semiconductor bonds. In an aspect of the embodiment UHV part 102 of the production system for wafer bonding may optionally be equipped with one or several chambers containing surface analysis tools for in-situ wafer inspection prior to wafer bonding. These tools may for example comprise an atomic force microscope (AFM) for surface roughness measurements, and a spectrometer for X-ray photoelectron spectroscopy (XPS) or Auger electron spectroscopy (AES) tool for chemical surface analysis.

The second part 102 of the production system 100 for low-temperature covalent wafer bonding comprises a wafer handling chamber 144 which may be of a simpler design compared to wafer handler 104 with robot 148, for example, for linear wafer transfer. Except for buffer chamber 140 which is attached to central handler 104 and except for handling chamber 144 the modules of part 102 are designed for processing in a dry inert gas atmosphere essentially at atmospheric pressure. The inert gases may, for example, comprise high purity oxygen-free and water-free nitrogen or argon. Part 102 is equipped with load-lock 160 for the introduction of wafer cassettes carrying the wafers to be either wet chemically or vapour cleaned. After cassette loading load-lock 160 may be evacuated to a pressure of about 10⁻⁵ to 10⁻⁶ mbar before being filled with high purity N₂ or Ar at or near atmospheric pressure. Wet chemistry may be performed in at least one of a series of wet chemical processing modules or chambers 156₁-156ₙ, preferably made from stainless steel or PTFE (polytetrafluoroethylene), depending on the chemicals used inside. Each module from 156₁-156ₙ contains at least one tool from a list of tools, for example module 156₁ solvent baths for degreasing, module 156₂ acid baths for wafer dipping for example for a CAROS clean, module 156₃ and 156₄ baths for the SC1 and SC2 RCA wafer cleaning process, module 156₅ for wet chemical oxide removal by an HF-dip, and for example chamber 156₆ for an alternative oxide removal step by HF vapour, and chamber 156₇ for deionized water rinsing and spin drying. Wet chemical processing in chambers 156₁-156ₙ is again performed in a high purity N₂ or Ar atmosphere. Preferably, acid baths, deionized water rinse and inert gas lines are all equipped with particle filters, ensuring particle-free processing of all wafer surfaces. The natural oxide on Si wafers may be etched for example in module 156₅ by a dilute, aqueous 2-5% HF solution for about 15-60 seconds and subsequently spin-rinsed in module 156₇ by 18 MΩ deionized water upon which a H-passivated. Si surface is formed. For other semiconductor surfaces different etchants may be more appropriate, such as, for example, a 1:1 or more dilute solution of HCl:H₂O for GaAs. Alternatively, at least one of processing chambers, for example 156₆ may be equipped for wafer cleaning by etching gases or vapours, for example, HF vaporized from a HF/water solution or anhydrous HF gas (see, for example, P. A. M. van der Heide et al. in J. Vac. Sci. Technol. A 7, 1719 (1989), the entire disclosure of which is hereby incorporated by reference). The atmospheric pressure modules 156₁-156ₙ are separated from handling chamber 144 by special corrosion resistant gate valves 164, optionally in addition to vacuum gate valve 152. Enclosing processing chambers 156₁-156ₙ by corrosion resistant valves 164 may permit easy and safe removal for servicing of all parts operated at or near atmospheric pressure. Wafer transfer from load-lock 160 to processing modules 156₁-156ₙ and further to buffer chamber 140 is carried out by robot 148. Handling chamber 144 is optionally heatable to 100°-200° C. and preferably equipped with a fast pump for evacuation to a pressure of about 10⁻⁴ to 10⁻⁶ mbar. Buffer chamber 140 may also be equipped with a heating stage permitting wafer heating to about 100°-200° C., for example, by heating lamps. This may be advantageous for evacuating the chamber to high vacuum of a pressure of about 10⁻⁷ to 10⁻⁸ mbar, for example, by a combination of oil-free pre-vacuum and turbomolecular pumps. Wafer transfer from atmospheric pressure chamber 156ₙ to UHV wafer handler 104 is therefore realized by a series of steps characterized by increasing vacuum quality.

The production system for semiconductor wafer bonding of the invention has a modular design, facilitating maintenance operations, as for example wet chemical chambers 156₁-156ₙ and load-lock 160 can safely be removed from vacuum system 101 for servicing. Similar ease of maintenance applies to vacuum chambers 116, 120, 120′, 124, 128, 132, 136, 140, 144, all of which can be mounted and remounted with the help of specially designed assembly/disassembly tooling without the need of breaking the vacuum in handler 104.

The production system for semiconductor wafer bonding of the invention may be operated fully automatically under computer control. Optionally, control computers offer remote access, for example, through the Internet or a remote desktop.

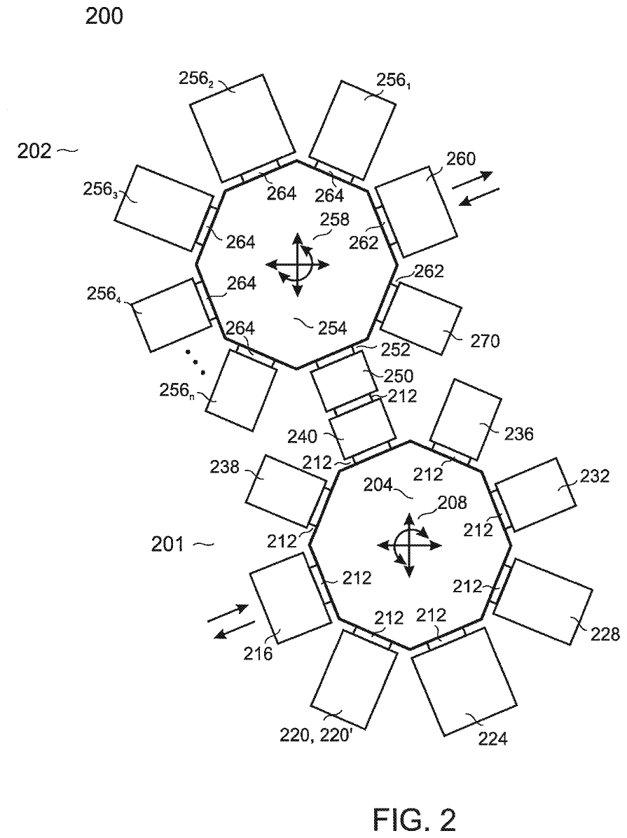

Referring now to FIG. 2, second embodiment 200 of a production system for low-temperature covalent bonding of semiconductor wafers up to 300 mm in size is made up of two connected parts 201, 202 both of which contain central wafer handlers 204, 254 with robots 208, 258. A first part 201 is a vacuum system with modules all of which are compatible with ultra-high vacuum processing and connected via UHV compatible gate valves 212 with central handler 204. The second part 202 is a system operating essentially at atmospheric pressure with modules designed for wet chemical or vapour processing. The two parts are connected through a buffer chamber 240 the purpose of which is to avoid cross-contamination. Both parts are furthermore accessible through separate load locks 216, 260. Embodiment 200 has the advantage of easier and faster wafer handling in comparison to embodiment 100 which comprises linear wafer transfer in part 102. The chambers and their purposes are, however, essentially similar for embodiments 100 and 200 which is why they will not be described in equally detailed form. Thus vacuum system 201 contains plasma processing chamber 220, preferably equipped with a rotatable wafer stage which may optionally be heated to temperatures of about 100°-300° C. for easier removal of the hydrogen passivation present on the wafer surfaces. Alternatively, process chamber 220′ may be a UHV laser processing chamber equipped for UV laser exposure of the surfaces, the laser providing photon energies in a range of about 2-10 eV, permitting either photochemical or photo-thermal hydrogen desorption from passivated semiconductor surfaces. Laser processing chamber 220′ may be equipped with a rotatable wafer stage and with an auxiliary heater for uniform heating of the back of a wafer. The control of the wafer surface temperature may be provided by an infrared temperature sensor. The sensor may be mounted on a tilt module, permitting infrared radiation emitted from any point between the center and edge of the wafer to be measured. A feedback loop between the sensor and the rotation speed of the wafer stage and the power of the laser may provide real time control of the surface temperature at any location on the wafer.

In an aspect of the embodiment chambers 220, 220′ may be present as two separate chambers attached to central handler 204, one for plasma processing and the other for laser processing, permitting more flexibility for example for the removal of the hydrogen passivation from different semiconductor surfaces. Production system 200 for low-temperature covalent wafer bonding comprises further at least one UHV bonding chamber 224 equipped with a wafer alignment system which permits the wafer pair to be mutually aligned with a precision of, for example, 50-200 nm prior to bonding. Preferably, entire bonding chamber 224 is temperature controlled within about 0.5°-1° C., or preferably within 0.1°-0.5° C., or even more preferably within 0.05°-0.1° C. Bonding chamber 224 may furthermore be vibrationally decoupled by a bellows from wafer handler 204 to facilitate accurate wafer alignment. Embodiment 400 of a wafer alignment system which is easily scalable to the bonding of 300 mm wafers will be introduced further below. Part 201 of the production system 200 for low-temperature covalent wafer bonding may further comprise wafer alignment UHV chamber 232 for wafer pre-alignment. Therein wafers may be pre-aligned rotationally to within a precision of about 0.1-0.5°, and translationally to within about 50-200 μm. Unless small features on the bonding partners need to be aligned, this pre-alignment may be sufficiently accurate for most applications of covalent bonding. Optionally, the pre-alignment of wafers may be carried out in handler 204 instead of a separate UHV chamber 232. Apart from a UHV wafer flipping chamber 236 and a thin film deposition chamber 238, equipped with substrate heater and tools for plasma assisted CVD or for thin film deposition in UHV similar to chamber 138, UHV vacuum system 201 may optionally comprise additional chambers, for example an annealing chamber 228 for post-bonding annealing or for pre-bonding single wafer annealing up to a maximum temperature of about 900° C. Single wafer annealing may be used for example for the hydrogen desorption from semiconductor wafers which do not present any thermal budget problem, such as passivated Si or Ge wafers for which complete thermal H-desorption requires temperatures of at most 600° C. and 400° C., respectively.

Optionally, UHV part 201 of the production system for low-temperature covalent semiconductor wafer bonding may furthermore be equipped also with a wafer storage chamber with a base pressure preferably in the range of 1×10⁻¹¹ to 5×10⁻¹¹ mbar, permitting hydrogen passivated wafers transferred from essentially atmospheric pressure part 202 to be stored for extended periods of time (e.g. for example one day). Such a chamber may act as a buffer to facilitate the synchronisation of processes requiring different processing times in order to increase the throughput of the wafer bonding system 200 as a whole.

Part 202 of the production system for wafer bonding contains a series of processing modules arranged around central handler 254 equipped with robot 258. Wafers are introduced through load-lock 260 connected via gate valve 262 with central handler 254 and transferred into a series of modules 256₁ . . . 256ₙ designed for wet chemical and/or gas phase cleaning all of which are connected to central handler 254 through corrosion resistant gate valves 264. Chamber 256₁ may be a chamber equipped with solvent baths for degreasing of wafers, chamber 256₂ for example for a CAROS clean, chamber 256₃ and 256₄ for the SC1 and SC2 steps of well-known RCA cleaning, chamber 256₅ for wet chemical oxide removal by an HF-dip, and for example chamber 256₆ for an alternative oxide removal step by HF vapour, and chamber 256₇ for deionized water rinsing and spin drying. Optional chamber 270 may for example serve as a storage chamber for wafers from a cassette introduced through load-lock 260. Chamber 270, connected via gate valve 262 to central handler 254, can optionally be evacuated and/or filled with a inert gas atmosphere. Atmospheric pressure part 202 is separated from UHV part 201 by a buffer chamber 250 or preferably two buffer chambers 240, 250 successively pumped from atmospheric pressure to UHV in order to avoid cross-contamination between atmospheric pressure and UHV part.

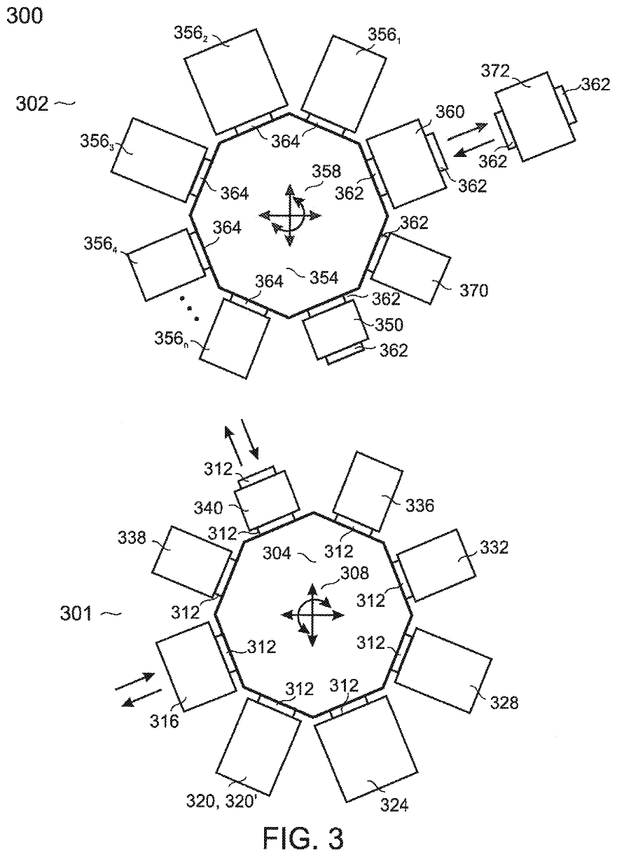

Referring now to FIG. 3, third embodiment 300 of a production system for low-temperature covalent bonding of semiconductor wafers up to 300 mm in size is made up of two separate parts 301, 302 both of which contain central wafer handlers 304, 354 with robots 308, 358. A first part 301 is a vacuum system with modules all of which are compatible with ultra-high vacuum processing. The second part 302 is a system operating essentially at atmospheric pressure with modules designed for wet chemical or vapour processing. The two parts are normally disconnected and communicate by means of UHV suitcase 372 which can be attached either to load-lock 360 of the second part 302 or to buffer chamber 340 of part 301 serving as a second load-lock on that system. Part 301 is furthermore accessible through load lock 316. Embodiment 300 has the advantage of easier servicing in comparison to embodiments 100, 200 because atmospheric pressure and UHV parts are normally separate. The chambers and their purposes are, however, essentially similar for embodiments 200 and 300 which is why they will not be described in equally detailed form. Thus vacuum system 301 contains plasma processing chamber 320, preferably equipped with a rotatable wafer stage which may optionally be heated to temperatures of about 100°-800° C. for easier removal of the hydrogen passivation present on the wafer surfaces. Alternatively, process chamber 320′ may be a UHV laser processing chamber equipped for UV laser exposure of the surfaces, the laser providing photon energies in a range of about 2-10 eV, permitting either photochemical or photo-thermal hydrogen desorption from passivated semiconductor surfaces. Laser processing chamber 320′ may be equipped with a rotatable wafer stage and with an auxiliary heater for uniform heating of the back of a wafer. The control of the wafer surface temperature may be provided by an infrared temperature sensor. The sensor may be mounted on a tilt module, permitting infrared radiation emitted from any point between the center and edge of the wafer to be measured. A feedback loop between the sensor and the rotation speed of the wafer stage and the power of the laser may provide real time control of the surface temperature at any location on the wafer.

In an aspect of the embodiment chambers 320, 320′ may be present as two separate chambers attached to central handler 304, one for plasma processing and the other for laser processing, permitting more flexibility for example for the removal of the hydrogen passivation from different semiconductor surfaces. Production system 300 for low-temperature covalent wafer bonding comprises further at least one UHV bonding chamber 324 equipped with a wafer alignment system which permits the wafer pair to be mutually aligned with a precision of, for example, 50-200 nm prior to bonding. Preferably, entire bonding chamber 324 is temperature controlled within about 0.5°-1° C., or preferably within 0.1°-0.5° C., or even more preferably within 0.05°-0.1° C. Bonding chamber 324 may furthermore be vibrationally decoupled by a bellows from wafer handler 304 to facilitate accurate wafer alignment. Embodiment 400 of a wafer alignment system which is easily scalable to the bonding of 300 mm wafers will be introduced below. Part 301 of the production system 300 for low-temperature covalent wafer bonding may further comprise wafer alignment UHV chamber 332 for wafer pre-alignment. Therein wafers may be pre-aligned rotationally to within a precision of about 0.1-1°, and translationally to within about 50-200 μm. Unless small features on the bonding partners need to be aligned, this pre-alignment may be sufficiently accurate for most applications of covalent bonding. Optionally, the pre-alignment of wafers may be carried out in handler 304 instead of a separate UHV chamber 332. Apart from UHV a wafer flipping chamber 336 and a thin film deposition chamber 338, equipped with substrate heater and tools for plasma assisted CVD or for thin film deposition in UHV similar to chamber 138, UHV vacuum system 301 may optionally comprise additional chambers, for example an annealing chamber 328 for post-bonding annealing or for pre-bonding single wafer annealing up to a maximum temperature of about 900° C. Single wafer annealing may be used for example for the hydrogen desorption from semiconductor wafers which do not present any thermal budget problem, such as passivated Si or Ge wafers for which complete thermal H-desorption requires temperatures of at most 600° C. and 400° C., respectively.

Optionally, UHV part 301 of the production system for low-temperature covalent semiconductor wafer bonding may furthermore be equipped also with a wafer storage chamber with a base pressure preferably in the range of 1×10⁻¹¹ to 5×10⁻¹¹ mbar, permitting hydrogen passivated wafers transferred by means of UHV suitcase 372 from essentially atmospheric pressure part 302 to be stored for extended periods of time (e.g. for example one day). Such a chamber may act as a buffer to facilitate the synchronisation of processes requiring different processing times in order to increase the throughput of the wafer bonding system 300 as a whole.

Part 302 of the production system for wafer bonding contains a series of processing modules arranged around central handler 354 equipped with robot 358. Wafers are introduced through load-lock 360 and transferred into a series of modules 356₁ . . . 356ₙ designed for wet chemical and/or gas phase cleaning and connected via corrosion resistant gate valves 364 to central handler 254 Chamber 356₁ may be a chamber equipped with solvent baths for degreasing of wafers, chamber 256₂ for example for a CAROS clean, chambers 356₃ and 356₄ for the SC1 and SC2 steps of well-known RCA cleaning, chamber 356₅ for wet chemical oxide removal by an HF-dip, and for example chamber 356₆ for an alternative oxide removal step by HF vapour, and chamber 256₇ for deionized water rinsing and spin drying. Optional chamber 370 may for example serve as a storage chamber for wafers from a cassette introduced through load-lock 360. Optionally, after servicing, part 302 can be coupled to part 301 for example through buffer chambers 340, 350 connected through UHV gate valves 312, 362, after which the bonding system of embodiment 300 may become identical with that of embodiment 200.

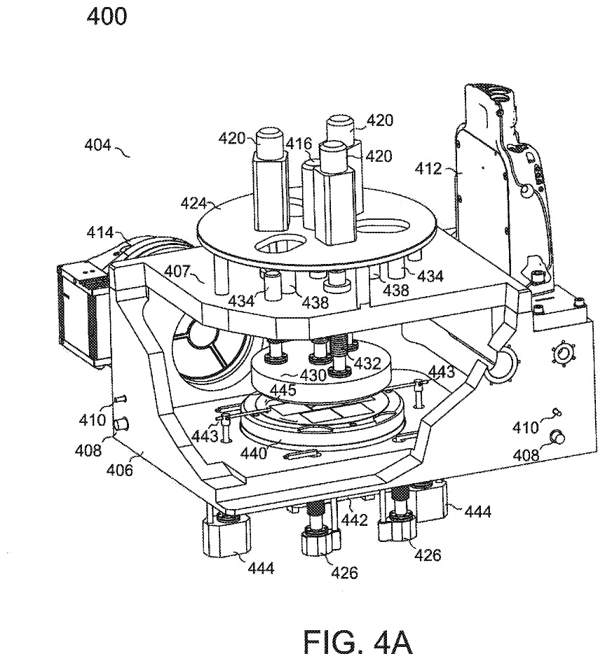

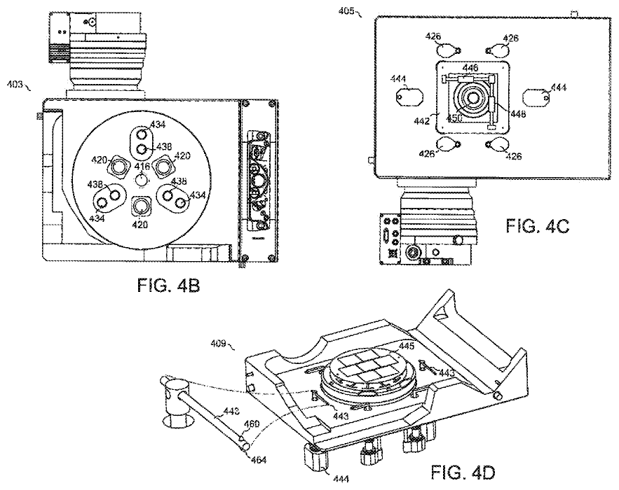

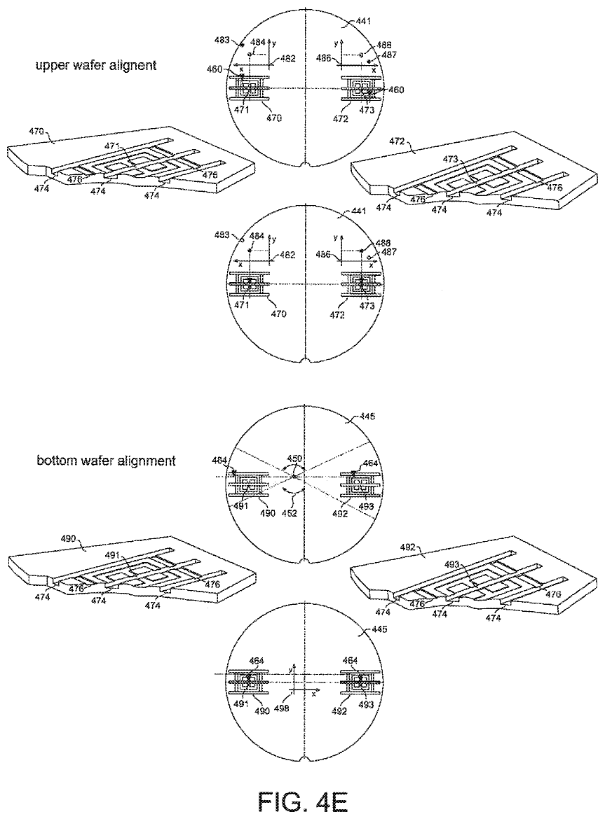

Referring now to FIG. 4A, embodiment 400 the walls 406 of bonding chamber 404 are substantially made from welded metal or machined from a monolithic block and are temperature stabilized within about 0.5°-1° C., or preferably within 0.1°-0.5° C., or even more preferably within 0.05°-0.1° C. Heating of chamber walls 406 is accomplished by several heating cartridges 408 distributed approximately uniformly over its body in order to guarantee uniform temperature control. The temperature is controlled and measured by temperature sensors 410 the number of which equals at least the number of heating cartridges 408. Optionally, chamber 404 may be vibrationally decoupled from handler 104, 204, 304 for example by a rectangular bellows. UHV gate valve 412 is arranged on the body of the metal block, such that it can be serviced without any need to detach the bonding chamber from central handler 104, 204, 304.

After pre-alignment of the wafers in pre-alignment tool 132, 232, 332, and introduction into bonding chamber 404 the wafers are picked and placed by pins 426 onto electrostatic chucks or chuck modules 430, 440 which may optionally comprise integrated active heating and/or cooling. After activating the electrostatic chucks, keeping the wafers firmly held, pins 426 are retracted before the alignment procedure begins.

Bonding chamber 404 is equipped with an actuator in the form of a small electric piston 416 aligned with the central axis of the wafer alignment system. One set of at least three actuators in the form of pistons 420 is arranged symmetrically at equal distance from central piston 416 (see also top view 403 of chamber 404 in FIG. 4B). The casings of all pistons are firmly mounted on rigid plate 424. The pistons move in ultra-precision shafts and can be electrically driven by motors chosen from a plurality of motors, such as stepper motors, DC motors, linear motors, brushless DC motors, etc. They act through moving bellows 432 on upper electrostatic chuck module 430, keeping it accurately parallel to bottom electrostatic chuck module 440. The electrical motors permit both parallelism control and the application of the desired bonding pressure once the wafers have come into contact. For the linear movement of the pistons preferably high precision inverted planetary roller screw spindles are being used, manufactured for example by Schaeffler (schaeffler.com) and Rollvis Swiss (rollvis.com). As an example, for a 20 mm shaft, the pitch of the screw is 1.35 mm. For every angular degree of rotation, the shaft therefore moves by 3.75 μm. With an additional gearbox, providing for example a gear ratio of 100, a resolution of 37.5 nm can hence be achieved. Harmonic Drive LLC (harmonicdrive.net) have in their portfolio for example a linear actuator with a resolution of 160 nm. For the control of parallelism two sets of confocal interferometric sensors are mounted on top lid 407 of chamber 406. Confocal interferometric sensors offer a resolution in the tens of nm range, for example a resolution of 16 nm as advertised by Micro-Epsilon in their product range (micro-epsilon.com). The first set of at least three inner sensors 438 are used to keep the top chuck module horizontal and parallel to lid 407 of chamber 406 during its lowering towards bottom chuck module 440. The second set of at least three outer sensors 434 serve for the ultra-precise parallel alignment of upper chuck module 430 to bottom chuck module 440 once they have come close. Bottom electrostatic chuck module is mounted on translational stage 442 which can be translated in x- and y-direction by ±2 mm by high precision mechanical actuators 446 and 448, respectively. Translational stage 442 is shown in greater detail in the bottom view 405 of chamber 404 of FIG. 4C. Stage 442 can in addition be rotated as a whole around central rotation axis 450. According to the invention all high precision mechanisms necessary for keeping top and bottom wafers parallel and assuring rotational and translational alignment are thus positioned outside the UHV environment, making servicing very easy.

Similar to the vertical wafer alignment, the rotational and translational wafer alignment is again controlled by confocal interferometric sensors 443. These are mounted on a set of at least two rotatable and translatable actuators 444 by means of which they can be moved into measurement positions between the wafers as in FIG. 4A or to a home position before the final approach of the wafers for bonding (FIG. 4D). Actuators 444 in the set of at least two actuators are preferably positioned on opposite sides of chuck modules 430, 440 to allow sensors 443 to find alignment features 470, 472 and 490, 492, all of which are identical, on opposite extremes of upper wafer 441 and lower wafer 445, respectively (FIG. 4E). Actuators 444 each comprise a scanning unit, such as piezo actuators, permitting their scanning in x-y directions in coordinate systems 482, 486, once sensors 443 have been rotated into their measurement positions. The sensors may for example comprise optical fibers with grating, lenses and a prism serving for 90° vertical beam deflection. In sensors 443 two such sets are contained, one for upwards focused beam 460 and the other for downwards focused beam 464, which are accurately aligned along a vertical axis (perpendicular to the wafer plane) with respect to each other. Preferably, the deviation from the vertical is kept in the range of about 10⁻⁴-10⁻³ angular degrees. After parallel alignment the wafers may be separated by a distance in the range of about 8 to 20 mm, sufficient to move sensors 443 to the measurement position approximately 2.7 mm above bottom wafer 445 and below upper wafer 441, respectively.

All that is needed for precise wafer alignment in the sub-100 nm range are some alignment features 470, 472, 490, 492 at the periphery of both wafers providing a contrast for the reflected focused beams (FIG. 4D, E). This may be contrast due to a surface profile, for example caused by trenches 474, 476 of different depth, or preferably by material contrast (e.g. oxide/semiconductor), the latter being compatible with planarized wafers to be bonded. Alignment is accomplished by first scanning sensors 443 on both extremes of upper wafer 441 in x-y directions to find and image alignment features 470, 472 on upper wafer 441. Once alignment features 470, 472 have been recognized and imaged, this permits upwardly focused beams 460 to be moved from initially random positions 483 and 487 precisely moved into centers 484, 488, 471, 473 of alignment features 470, 472 (FIG. 4E). After centering of beams 460, sensors 443 remain stationary, while bringing corresponding features 490, 492 on bottom of wafer 445 into coincidence. The latter is achieved by activating stage 442 rotation around axis 450. By rotational scanning of alignment features 490, 492 on bottom wafer 445, deeper trenches 474 can be recognized by downward focused beam 464, thereby generating an image of the trench profile, permitting alignment features 490, 492 to be rotationally aligned with corresponding features 470, 472 on upper wafer 441. Thus the trenches of upper and bottom wafer are for example aligned along the x-axis of coordinate system 498 (FIG. 4E). The precise positioning of beams 464 into the centers 491, 493 of alignment features 490, 492 on bottom wafer 445 is performed by scanning stage 442 with mechanical actuators 446, 448 in the x-y directions of coordinate system 498. The images thereby generated help to locate the coordinates of alignment features 490, 492 to permit actuators 446, 448 to move downwardly focused beams 646 precisely into features centers 491, 493 (FIG. 4C, E).

During all rotational and translational movements, the wafers are permanently kept parallel by actuating pistons 420. After completing the alignment, sensors 443 are rotated to home position. The final wafer approach happens during permanent compensation of any deviation from wafer parallelism until central piston 416 can be actuated to start the bonding wave after initial contact of the wafers. Thereafter, in order to apply a constant pressure homogeneously distributed across the wafers, actuators 420 operate under torque control. Optionally, additional optical cameras may facilitate course wafer alignment. Moreover, one or several laser interferometers accessing chuck modules 430, 440 through windows in chamber 406 may provide absolute alignment reference points correcting for any undesired internal movements for example as a result of thermal non-uniformities. Any chamber deformation during the application of the bonding forces exerted by actuators 420 may be monitored by pressure gauges distributed over chamber 406.

It is an advantage of the invention that wafer alignment does not require infrared transparency. By contrast, any bondable wafer whatever its nature can be used in the described approach.

Referring now to FIG. 5, embodiment 500 of plasma processing chamber 504 is substantially made from welded metal or machined from a monolithic block 506. UHV gate valve 512 is arranged on the body of the metal block, such that it can be serviced without any need to detach the bonding chamber from central handler 104, 204, 304. Plasma processing chamber 504 is preferably pumped by turbo-molecular pump 514. Low energy plasma source 516 mounted on lid 508 of plasma chamber 504 may for example be an inductively coupled plasma source which can be operated with different discharge gases, such as H, N₂, He, Ar, Ne, Kr or mixtures thereof. More generally, plasma source 516 may be any plasma source capable of providing low energy ions in the range of about 10-20 eV or even 5-10 eV, suitable for hydrogen removal but sufficiently gentle to avoid surface amorphization of the treated wafers. The gas lines supplying the low-energy plasma source are preferably all equipped with sorption filters removing traces of water and oxygen, along with particle filters known in the art. Plasma chamber 504 is further equipped with integrated module 530 equipped for radiative heating of wafer 528 resting on cradle 526 from the back by heater 520 to temperatures of about 100°-300° C. Heating of wafer 528 further reduces the likelihood of surface amorphization and/or implantation of gas particles during the plasma treatment process. Peripheral heat shield 522 and bottom heat shield 524 enhance temperature uniformity and heat transfer to wafer 528. Apart from hosting heater 520 and shields 522, 524 integrated module 530 contains a mechanism for lifting wafer 528 above the level of peripheral heat shield 522, such that it can easily be picked up by robot 108, 208, 308 and transferred to wafer handler 104, 204, 304. Integrated module 530 further provides uniform plasma exposure of wafer 528 by a mechanism for rotating cradle 526 up to a speed of about 100 rpm. Optionally, integrated module 530 also comprises a mechanism for wafer tilt. Plasma chamber 504 is further equipped with remote laser heating module 540 with different beam sectors 542, which can be powered independently, providing intense laser irradiation to increase the surface temperature of wafer 528, or to promote hydrogen desorption by direct photochemical reaction, Laser irradiation by module 540 may for example be realized by an array of visible or UV laser diodes adapted for providing just local surface heating as result of appropriately chosen wavelengths for small penetration depth. For example for silicon photon energies Eₚₕ between about 2.5 and 10 eV, corresponding to wavelengths λ between green and far ultraviolet (λ[μm]=1.24/Eₚₕ[eV]), are suitable for local surface heating of rotating wafer 528. Laser exposure of the entire wafer surface is thereby guaranteed by the rotating wafer stage. Optionally, for easier maintenance, laser heating module 540 may be placed outside plasma chamber 504, accessing the wafer through a window. Control of the local surface temperature of wafer 528 is provided by temperature sensor 544. Sensor 544 is mounted on tilt module 532 by means of which infrared radiation 546 emitted from any radial distance between the center and edge of wafer 528 can be measured. A feedback loop between sensor 544, rotation speed of cradle 526 and power applied to different beam sectors 542 of laser module 540 may provide real time control of the surface temperature at any location on wafer 528. Optionally, also sensor 544 may be placed outside plasma chamber 504 for easier maintenance.

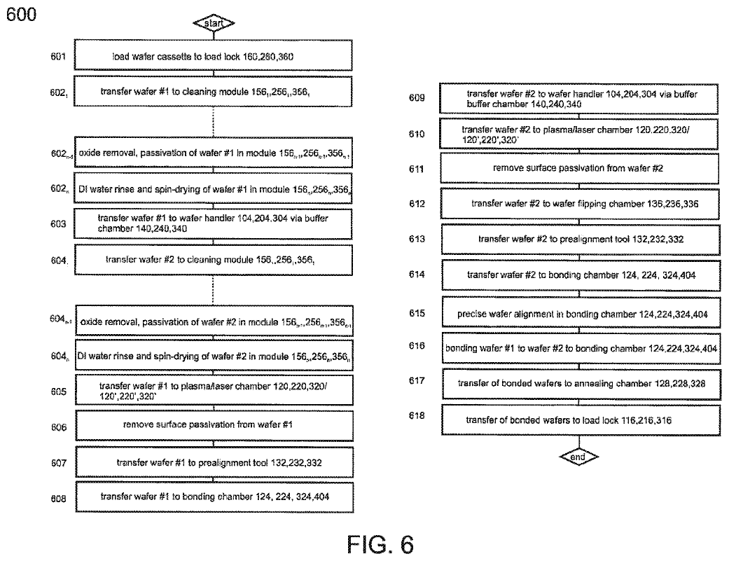

Referring now to FIG. 6, first embodiment 600 of a process sequence for covalent, oxide-free semiconductor bonding may comprise the following steps, the order of some of which may optionally be interchanged and/or carried out at the same time. In step 601, at least one wafer cassette is loaded into load lock 160, 260, 360. Optionally, load lock 160, 260, 360 may then be evacuated before being filled with an inert gas atmosphere at or near atmospheric pressure. In step 602₁, a first wafer #1 is picked up from the wafer cassette by robot 148, 258, 358 and transferred into processing module 156₁, 256₁, 356₁, wherein it may for example be degreased. Wafer #1 then undergoes a number of additional cleaning steps 602₂, 602₃, . . . 602ₙ₋₂, depending on the number n of cleaning modules present in part 102, 202, 302 of production system 100, 200, 300 for wafer bonding. These steps may for example comprise SC1 and SC2 steps of the well-known RCA wafer cleaning process for the removal of metal and other contaminants from the wafer surfaces. In step 602ₙ₋₁, depending on the semiconductor material wafer #1 is made of, the latter may be subject to liquid or gas etching and passivation by dedicated chemical etchants in module 156ₙ₋₁, 256ₙ₋₁, 356ₙ₋₁. Wet chemical surface cleaning may consist of etching with HCl, or dilute HF followed by a deionized (DI) water rinse. The natural oxide on Si wafers may, for example, be removed by etching for 15-60 seconds in a dilute HF solution (for example, 5% in water), followed by spin-rinse drying. Alternatively, the natural oxide on Si wafers may be removed by HF gas etching from an HF/H₂O batch stabilized at a temperature, for example, of 25° C. This method was shown to remove very efficiently also any sub-oxides present at the SiO₂/Si interface (see, for example, P. A. M. van der Heide et al, in J. Vac, Sci. Technol. A 7, 1719 (1989), the entire disclosure of which is hereby incorporated by reference). It is an advantage of the invention that both liquid and gaseous HF etching are carried out under an inert nitrogen or argon atmosphere, and that the clean semiconductor surfaces never have to be exposed to air before being processed in the UHV part of the bonding tool. This excludes any undesirable re-oxidation of the surfaces. A final optional step 602 in processing module 156ₙ, 256ₙ, 356ₙ may consist of a deionized water rinse with megasonic agitation for particle removal and spin-drying. In step 603 wafer #1 is transferred to the UHV part of the bonding tool by robot 148, 258 or by means of UHV suitcase 372. In embodiments 100 and 200 first wafer #1 enters wafer handling chamber 144 or additional buffer chamber 250, respectively, which is rapidly pumped to 10⁻⁴ to 10⁻⁶ mbar after the closing of gate valve 152, 252. Wafer #1 is then transferred to buffer chamber 140, 240 wherein it may optionally be heated to about 100°-200° C., facilitating pumping of this chamber to high vacuum of a pressure of about 10⁻⁸ mbar, and finally to central wafer handler 104, 204. Alternatively, in embodiment 300, wafer #1 is loaded to load-lock 360, which is rapidly pumped to 10⁻⁴ to 10⁻⁶ mbar after the closing of gate valve 362. Wafer #1 is then transferred to UHV suitcase 372 which after pumping to at least 10⁻⁸ mbar can dock at buffer chamber 340 before being transferred to handler 304. Meanwhile, in step 604₁, wafer #2 is picked up from the wafer cassette in load lock 160, 260, 360 by robot 148, 258, 358 and transferred into processing module 156₁, 256₁, 356₁, wherein it may for example be degreased. Wafer #2 then undergoes the same cleaning steps 604₂, 604₃, . . . 604ₙ, including oxide removal and deionized water rinse/spin drying as those of wafer #1 if both wafers are made from the same semiconductor material. Alternatively, different etchants may be used in case that the two wafers differ in composition. In step 605, wafer #1 is transferred to UHV laser processing chamber 120′, 220′, 320′ or plasma processing chamber 120, 220, 320 by robot 108, 208, 308. The removal of the surface passivation in step 606 may occur in a number of ways, depending on the way in which chambers 120, 220, 320, 120′, 220′, 320′ are equipped and depending on the semiconductor material wafer #1 is made of. The removal of the surface passivation may comprise low energy plasma exposure, optionally keeping the wafer at elevated temperature for example in a range of 100° C.-200° C., or 200° C.-300° C. in cases in which a low thermal budget is required, as for example for CMOS processed wafers. Less delicate wafers may undergo plasma exposure at a higher temperature of 300° C.-400° C. or even higher. In addition to or instead of surface bombardment by low energy ions in the plasma may wafer #1 may be subjected to light with a low penetration depth, providing energy just to the surface of the semiconductor. For example for silicon green, blue or UV light may be employed, for example by irradiating the surface with high power LEDs or semiconductor lasers or other lasers. In a preferable aspect of the embodiment the wafer is rotated during the plasma exposure and/or light irradiation. Taking the example of low energy ion bombardment, for example, by the inductively coupled Copra DN250 CF plasma source from CCR Technology, nearly mono-energetic argon or neon ions can be obtained in the range of 12-15 eV at a distance of about 25 cm between the substrate and the plasma source orifice for chamber pressures on the order of 2.4×10⁻³ mbar. For instance, this permits passivating surface hydrogen on a Si surface to be eliminated without risking amorphization. In step 607, wafer #1 is transferred to pre-alignment tool 132, 232, 332, wherein it may be pre-aligned rotationally to within a precision of about 0.1-1°, and translationally to within about 50-200 μm. In subsequent step 608, wafer #1 is transferred to bonding chamber 124, 224, 324, 404 for example onto the lower chuck of the bonding tool. Meanwhile, in step 609, wafer #2 is transferred to the UHV part of the bonding tool by robot 148, 258, or by means of UHV suitcase 372. In embodiments 100 and 200 second wafer #2 enters wafer handling chamber 144 or additional buffer chamber 250, respectively, which is rapidly pumped to 10⁻⁴ to 10⁻⁶ mbar after the closing of gate valve 152, 252. Wafer #2 is then transferred to buffer chamber 140, 240, wherein it may optionally be heated to about 100°-200° C., facilitating pumping of this chamber to high vacuum of a pressure of about 10⁻⁸ mbar and finally to central wafer handler 104, 204. Alternatively, in embodiment 300, wafer #2 is loaded to load-lock 360, which is rapidly pumped to 10⁻⁴ to 10⁻⁶ mbar after the closing of gate valve 362. Wafer #2 is then transferred to UHV suitcase 372 which after pumping to at least 10⁻⁸ mbar can dock at buffer chamber 340 before being transferred to handler 304. In step 609, wafer #2 is transferred to UHV laser processing chamber 120′, 220′, 320′ or plasma processing chamber 120, 220, 320 by robot 108, 208, 308. The removal of the surface passivation in step 611 may occur in a number of ways, depending on the way in which chambers 120, 220, 320, 120′, 220′, 320′ are equipped and depending on the material wafer #2 is made of. The removal of the surface passivation may comprise low energy plasma exposure, optionally keeping the wafer at elevated temperature for example in a range of 100° C.-200° C., or 200° C.-300° C. in cases in which a low thermal budget is required, as for example for CMOS processed wafers. Less delicate wafers may undergo plasma exposure at a higher temperature of 300° C.-400° C. or even higher. In addition to or instead of surface bombardment by low energy ions in the plasma may wafer #1 may be subjected to light with a low penetration depth, providing energy just to the surface of the semiconductor. For example for silicon green, blue or UV light may be employed, for example by irradiating the surface with high power LEDs or semiconductor lasers or other lasers. In a preferable aspect of the embodiment the wafer is rotated during the plasma exposure and/or light irradiation. Taking the example of low energy ion bombardment, for example, by the inductively coupled Copra DN250 CF plasma source from CCR Technology, nearly mono-energetic argon or neon ions can be obtained in the range of 12-15 eV at a distance of about 25 cm between the substrate and the plasma source orifice for chamber pressures on the order of 2.4×10⁻³ mbar. For instance, this permits the passivating surface hydrogen on a Si surface to be eliminated without risking amorphization. In step 612, wafer #2 is transferred to flipping chamber 136, 236, 336 in which it is flipped upside down in order for the clean surface to face the clean surface of wafer #1 in the subsequent bonding process. In step 613, wafer #2 is transferred to pre-alignment tool 132, 232, 332, wherein it may be pre-aligned rotationally to within a precision of about 0.1-1°, and translationally to within about 50-200 μm. In subsequent step 614, wafer #2 is transferred to bonding chamber 124, 224, 324, 404 for example onto the upper chuck of the bonding tool. In step 615, wafer #1 is accurately aligned to wafer #2 and in subsequent step 616 covalently bonded to wafer #2 in bonding chamber 124, 224, 324, 404. In case that no high precision wafer alignment is needed, the bonding process is straightforward and preferably carried out at room temperature, or, alternatively, at a temperature in the range of 100°-300° C. on wafers pre-aligned in tools 132, 232, 332. For high precision alignment optical markers on both wafers must be brought into coincidence by using the high precision translational and rotational movements offered by the actuators of bonding chamber 404. Bonding pressures may range, for example, between about 0 and 100 kN. Optionally, in step 617 the bonded wafer pair may be transferred to annealing chamber 128, 228, 328, wherein it may be annealed to within 100°-800° C. for a prescribed period of time. In final step 618 the bonded wafer pair is transferred to a wafer cassette in load lock 116, 216, 316 of production system 100, 200, 300.

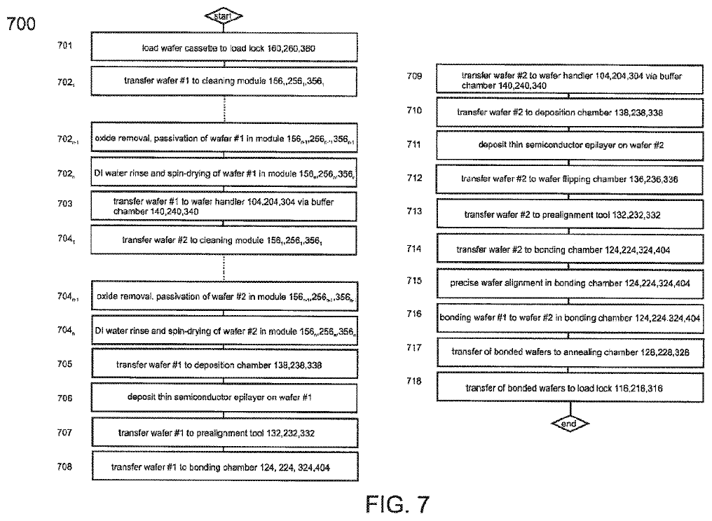

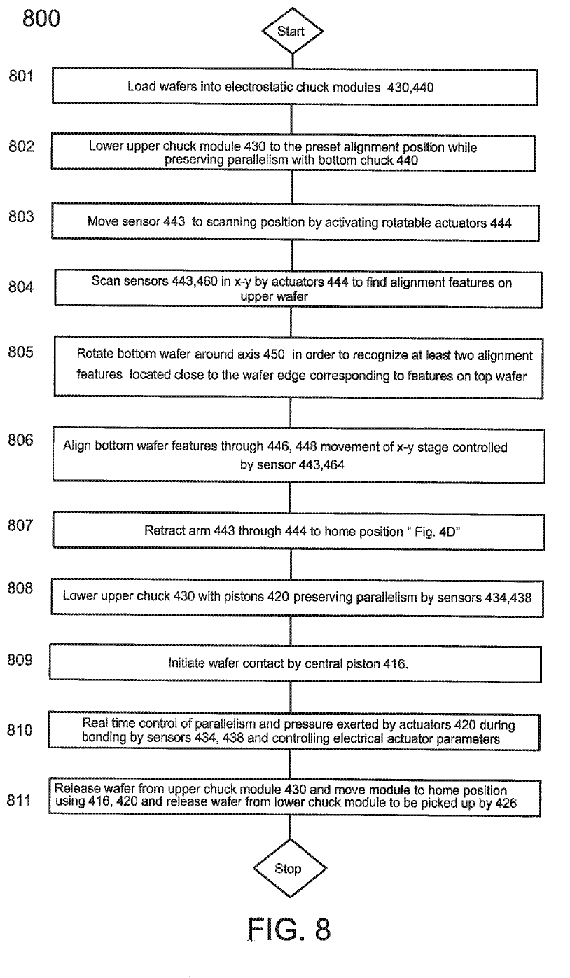

Referring now to FIG. 7, second embodiment 700 of a process sequence for covalent, oxide-free semiconductor bonding may comprise the following steps, the order of some of which may optionally be interchanged and/or carried out at the same time. In step 701, at least one wafer cassette is loaded into load lock 160, 260, 360. Optionally, load lock 160, 260, 360 may then be evacuated before being filled with an inert gas atmosphere at or near atmospheric pressure. In step 702₁, a first wafer #1 is picked up from the wafer cassette by robot 148, 258, 358 and transferred into cleaning module 156₁, 256₁, 356₁, wherein it may for example be degreased. Wafer #1 then undergoes a number of additional cleaning steps 702₂, 702₃, . . . 702ₙ₋₂, depending on the number n of cleaning modules present in part 102, 202, 302 of production system 100, 200, 300 for wafer bonding. These steps may for example comprise SC1 and SC2 steps of the well-known RCA wafer cleaning process for the removal of metal and other contaminants from the wafer surfaces. In step 702ₙ₋₁, depending on the semiconductor material wafer #1 is made of, the latter may be subject to liquid or gas etching and passivation by dedicated chemical etchants in module 156ₙ₋₁, 256ₙ₋₁, 356ₙ₋₁. Wet chemical surface cleaning may consist of etching with HCl, or dilute HF followed by a deionized (DI) water rinse. The natural oxide on Si wafers may, for example, be removed by etching for 15-60 seconds in a dilute HF solution (, for example, 5% in water), followed by spin-rinse drying. Alternatively, the natural oxide on Si wafers may be removed by HF gas etching from an HF/H₂O batch stabilized at a temperature, for example, of 25° C. This method was shown to remove very efficiently also any sub-oxides present at the SiO₂/Si interface (see, for example, P. A. M. van der Heide et al. in J. Vac. Sci. Technol. A 7, 1719 (1989), the entire disclosure of which is hereby incorporated by reference). It is an advantage of the invention that both liquid and gaseous HF etching are carried out under an inert nitrogen atmosphere, and that the clean semiconductor surfaces never have to be exposed to air before being processed in the UHV part of the bonding tool. This excludes any undesirable re-oxidation of the surfaces. A final optional step 702ₙ in processing module 156ₙ, 256ₙ, 356ₙ may consist of a deionized water rinse with megasonic agitation for particle removal and spin-drying. In step 703 wafer #1 is transferred to the UHV part of the bonding tool by robot 148, 258 or by means of UHV suitcase 372. In embodiments 100 and 200 wafer #1 enters wafer handling chamber 144 or additional buffer chamber 250, respectively, which is rapidly pumped to 10⁻⁴ to 10⁻⁶ mbar after the closing of gate valve 152, 252. Wafer #1 is then transferred to buffer chamber 140, 240, wherein it may optionally be heated to about 100°-200° C., facilitating pumping of this chamber to high vacuum of a pressure of about 10⁻⁸ mbar, and finally to central wafer handler 104, 204. Alternatively, in embodiment 300, wafer #2 is loaded to load-lock 360, which is rapidly pumped to 10⁻⁴ to 10⁻⁶ mbar after the closing of gate valve 362. Wafer #2 is then transferred to UHV suitcase 372 which after pumping to at least 10⁻⁸ mbar can dock at buffer chamber 340 before being transferred to handler 304. Meanwhile, in step 704₁, wafer #2 is picked up from the wafer cassette in load lock 160, 260, 360 by robot 148, 258, 358 and transferred into processing module 156₁, 256₁, 356₁, wherein it may for example be degreased. Wafer #2 then undergoes the same cleaning steps 704₂, 704₃, . . . 704ₙ, including oxide removal and deionized water rinse/spin drying as those of wafer #1 if both wafers are made from the same semiconductor material. Alternatively, different etchants may be used in case that the two wafers differ in composition. In step 705 wafer #1 is transferred to thin film deposition chamber 138, 238, 338 by robot 108, 208, 308. In chamber 138, 238, 338 the surface of wafer #1 is modified in order to make it ready for covalent semiconductor bonding, for which the surface has to be clean, i.e. hydrogen and oxygen-free. In case that chamber 138, 238, 338 is equipped with evaporators for thin film growth rather than gas lines wafer #1 may optionally be transferred to wafer flipping chamber 136, 236, 336 in which it is flipped upside down, before being transferred to deposition chamber 138, 238, 338. The base pressure in chamber 138, 238, 338 is in the range of 10⁻⁹ to 10⁻¹⁰ or below with a negligible partial pressure of water guaranteed by chamber degassing at temperatures between 150° C. and 200° C. In step 706, a H-passivated Si surface can, for example, be transformed into a hydrogen-free Ge surface by epitaxially depositing 2 to 4 ML of Ge at a low rate of 5-20 ML/min or even 0.1-5 ML/min and at a CMOS compatible temperature, for example, between 150°-300° C. At sufficiently low deposition rate one expects an exchange reaction, whereby hydrogen adsorbed on the Si surface migrates to the Ge surface. In contrast to passivated Si surfaces which have to be heated to above 550° C. to render them H-free, the weaker Ge—H bonds permit complete H-desorption from a Ge surface already at temperatures around 300° C., for example, at 300°-350° C. or even 290°-320° C. In step 707, the clean, hydrogen-free wafer #1 is transferred to pre-alignment tool 132,232, 332 in which it is pre-aligned rotationally to within a precision of about 0.1-1°, and translationally to within about 50-200 μm. In step 708, wafer #1 is transferred to bonding chamber 124, 224, 324, 404, for example onto the lower chuck of the bonding tool, or, if wafer #1 has been flipped prior to thin film deposition, onto the upper chuck of the bonding tool. In step 709 wafer #2 is transferred to the UHV part of the bonding tool by robot 148, 258 or by means of UHV suitcase 372. In embodiments 100 and 200 wafer #2 enters wafer handling chamber 144 or additional buffer chamber 250, respectively, which is rapidly pumped to 10⁻⁴ to 10⁻⁶ mbar after the closing of gate valve 152, 252. Wafer #2 is then transferred to buffer chamber 140, 240 wherein it may optionally be heated to about 100°-200° C., facilitating pumping of this chamber to high vacuum of a pressure of about 10⁻⁸ mbar, and finally to central wafer handler 104, 204. Alternatively, in embodiment 300, wafer #2 is loaded to load-lock 360, which is rapidly pumped to 10⁻⁴ to 10⁻⁶ mbar after the closing of gate valve 362. Wafer #2 is then transferred to UHV suitcase 372 which after pumping to at least 10⁻⁸ mbar can dock at buffer chamber 340 before being transferred to handler 304. In step 710, wafer #2 is transferred from wafer handler 104, 254, 354 to deposition chamber 138, 238, 338 by robot 108, 208, 308. In chamber 138, 238, 338, the surface of wafer #2 is modified in order to make it ready for covalent semiconductor bonding, for which the surface has to be hydrogen and oxygen-free. In case that chamber 138, 238, 338 is equipped with evaporators for thin film growth rather than gas lines wafer #2 may optionally be transferred to wafer flipping chamber 136, 236, 336 in which it is flipped upside down, before being transferred to deposition chamber 138, 238, 338. The base pressure in chamber 138, 238, 338 is in the range of 10⁻⁹ to 10⁻¹⁰ mbar or below with a negligible partial pressure of water guaranteed by chamber degassing at temperatures between 150° C. and 200° C. In step 711, a H-passivated Si surface can, for example, be transformed into a hydrogen-free Ge surface by epitaxially depositing 2 to 4 ML of Ge at a low rate of 5-20 ML/min or even 0.1-5 ML/min and at a CMOS compatible temperature, for example, between 150°-300° C. At sufficiently low deposition rate one expects an exchange reaction, whereby hydrogen adsorbed on the Si surface migrates to the Ge surface. In contrast to passivated Si surfaces which have to be heated to above 550° C. to render them H-free, the weaker Ge—H bonds permit complete H-desorption from a Ge surface already at temperatures around 300° C., for example, at 300°-350° C. or even 290°-320° C. In step 712, clean, hydrogen-free wafer #2 is optionally transferred to flipping chamber 136, 236, 336 in which it is flipped upside down in order for the clean surface to face the clean surface of wafer #1 in the subsequent bonding process. In step 713, wafer #2 is transferred to pre-alignment tool 132, 232, 332 in which it is pre-aligned rotationally to within a precision of about 0.1-1°, and translationally to within about 50-200 nm. In step 714, wafer #2 is transferred to bonding chamber 124, 224, 324, 404, for example, onto the lower chuck of the bonding tool, if wafer #1 has been flipped prior to thin film deposition and is now resting on the upper chuck of the bonding tool. Alternatively, if wafer #1 has not been flipped prior to thin film deposition and is resting on the lower chuck, wafer #2 is transferred to the upper chuck of the bonding tool. In step 715, wafer #1 is accurately aligned to wafer #2 and in subsequent step 716 covalently bonded to wafer #2 in bonding chamber 124 224, 324, 404. In case that no high precision wafer alignment is needed, the bonding process is straightforward and preferably carried out at room temperature, or, alternatively, at a temperature in the range of 100°-300° C. on wafers pre-aligned in tools 132, 232, 332. For high precision alignment, optical markers on both wafers must be brought into coincidence by using the high precision translational and rotational movements offered by the actuators of bonding chamber 404. Bonding pressures may range, for example, between about 0 and 100 kN. Optionally, in step 717 the bonded wafer pair may be transferred to annealing chamber 128, 228, 328, wherein it may be annealed to within 100°-800° C. for a prescribed period of time. In final step 718, the bonded wafer pair is transferred to a wafer cassette in load lock 116, 216, 316 of production system 100, 200, 300.

Referring now to FIG. 8, embodiment 800 of a process sequence for alignment may comprise the following steps, the order of some of which may optionally be interchanged and/or carried out at the same time. In step 801 wafer #1 is inserted into bonding chamber 404 through gate valve 412 by robot 108, 208, 308 after having been processed in steps outlined in FIGS. 6, 7, followed by wafer #2 accordingly. Pins 426 are used for positioning upper wafer 441 onto upper chuck module 430 and bottom wafer 445 onto bottom chuck module 440, respectively. Immediately after positioning of a wafer the respective chuck is activated. In step 802 the upper chuck module 430 is lowered towards the bottom chuck 440 by mean of actuators 420 under closed loop position control by means of inner confocal interferometric sensors 438 designed for short working distance, in order to keep the top chuck horizontal and parallel to top lid 407.

Upon approaching the final position, super precise parallelism on the order of 100 nm is established through a second close loop control with outer sensors 434, designed for larger working distance so that they can be focused on bottom chuck module 440. The final position distance between the upper and lower chuck module 430, 440 should be in a range of 5 to 20 mm, most preferably about 10 mm.

In step 803 confocal sensors 443, firmly connected to fine resolution rotatable and translatable actuator 444 are moved in between the two wafers to a pre-set sensing area controlled by the position controller unit.

In step 804 actuators 444 start scanning in sensor coordinate systems 482, 486 in x-y directions in order to find geometrical alignment features 470, 472 present on upper wafer 441. The shape of the alignment features 470, 472 on upper wafer 441 are determined by correlating the spatial movement of sensors 443 in coordinate systems 482, 486 with the signal detected from upwards focused beam 460. Thereby it becomes possible to reconstruct the surface topography or also the material contrast of the alignment features because the sensor can discriminate between different optical properties of materials, and for example the depth of oxide layers or trenches. Once the scan has been carried out by at least two sensors 443 located on opposite extremes of the upper wafer 441, stages 444 move upwards focused beams 460 of sensors 443 from random positions on the wafer, corresponding to initial coordinates 483, 487 in sensor coordinate systems 482, 486, exactly into centers 471, 473 of the geometrical alignment features corresponding to scanner coordinates 484, 488, whereupon the reliability of the previous scans is checked again. After the precise positioning of upwards focused beams 460 into the centers 471, 473 of alignment marks 470, 472 of upper wafer 441, actuators 444 remain stationary during all subsequent alignment sequences. In step 805, the high accuracy alignment of bottom chuck 440 is carried out to which bottom wafer 445 is firmly attached. The first alignment controlled by downwards focused beam 464 of sensor 443 is performed by actuating rotation 450 of bottom chuck module 440 to orient alignment features 490, 492 of bottom wafer 445 parallel to alignment features 470, 472 of upper wafer 441. The rotational alignment of the alignment features on top and bottom wafer is thereby monitored by rotational scanning in clockwise and anti-clockwise directions, permitting deeper trenches 474 of alignment features 490, 492 to be recognized by downward focused beams 464. Having generated an image of the trench profile on bottom wafer 445 permits parallel alignment of the alignment features on upper and bottom wafers for example along the x-axis of coordinate system 498 by once more activating rotation 450.

After the parallel alignment of the features on two extremes of the bottom wafer with the corresponding ones on the upper wafer, the rotation of stage 442 around axis 450 is stopped. In step 806, the centering of downwards focused beams 464 starts by scanning actuators 446, 448 of stage 442 in the x-y directions of stage coordinate system 498 in order to find now precisely the centers 491, 493 of the geometrical alignment features present on bottom wafer 445. Once the downwards focused beams 464 of at least two sensors 443 on opposite extremes of bottom wafer 445 have been centered, the upper and bottom wafers are aligned with very high accuracy on the order of 100 nm or even less. The x-y motorized stages 446, 448 hold then the final position in place, and no other correction needs to be performed.

In step 807, arms 443 are retracted to their home position shown in FIG. 4D. This assures the absence of collisions for the subsequent actions, in which top chuck 430 approaches bottom chuck 440 in order to perform the bond between the two wafers. In step 808 actuators 420 driven by a closed loop position control governed by confocal distance sensor sets 438, 434 lowers upper chuck module 430 towards bottom chuck 440 while perfectly preserving the parallelism. In step 809, when the distance between the two chuck modules 430, 440 holding the wafers is on the order of hundreds of microns, central piston 416 is actuated, assuring the first contact between the two wafers and thus the bonding wave to start from the center of the wafers. In step 810 when the two wafer are in contact and the upper chuck module is 430 is pushing towards the bottom chuck 440, the controller enables another close loop control based on motor torque control. This assures a homogeneous pressure exerted by actuators 420 digitally controlled by pre-set parameters. In step 811, after bonding, the upper wafer is released from electrostatic chuck module 430 which is moved to home position, so that after releasing the lower wafer from electrostatic chuck module 440 the bonded wafers are ready to be picked up by pins 426 for the next process steps.

It should be appreciated that the particular implementations shown and herein described are representative of the invention and its best mode and are not intended to limit the scope of the present invention in any way.

Many applications of the present invention may be formulated. As will be appreciated by skilled artisans, the present invention may be embodied as a system, a device, or a method.

The invention may be summarized by the feature sets defined by the appended claims, incorporated in this specification by reference thereto.

The present invention is described herein with reference to block diagrams, devices, components, and modules, according to various aspects of the invention. Moreover, the system contemplates the use, sale and/or distribution of any goods, services or information having similar functionality described herein.

The specification and figures should be considered in an illustrative manner, rather than a restrictive one and all modifications described herein are intended to be included within the scope of the invention claimed. Accordingly, the scope of the invention should be determined by the appended claims (as they currently exist or as later amended or added, and their legal equivalents) rather than by merely the examples described above. Steps recited in any method or process claims, unless otherwise expressly stated, may be executed in any order and are not limited to the specific order presented in any claim. Further, the elements and/or components recited in apparatus claims may be assembled or otherwise functionally configured in a variety of permutations to produce substantially the same result as the present invention. Consequently, the invention should not be interpreted as being limited to the specific configuration recited in the claims.

Benefits, other advantages and solutions mentioned herein are not to be construed as critical, required or essential features or components of any or all the claims.

As used herein, the terms “comprises”, “comprising”, or variations thereof, are intended to refer to a non-exclusive listing of elements, such that any apparatus, process, method, article, or composition of the invention that comprises a list of elements, that does not include only those elements recited, but may also include other elements such as those described in the instant specification. Unless otherwise explicitly stated, the use of the term “consisting” or “consisting of” or “consisting essentially of” is not intended to limit the scope of the invention to the enumerated elements named thereafter, unless otherwise indicated. Other combinations and/or modifications of the above-described elements, materials or structures used in the practice of the present invention may be varied or adapted by the skilled artisan to other designs without departing from the general principles of the invention.

The patents and articles mentioned above are hereby incorporated by reference herein, unless otherwise noted, to the extent that the same are not inconsistent with this disclosure.

Other characteristics and modes of execution of the invention are described in the appended claims.

Further, the invention should be considered as comprising all possible combinations of every feature described in the instant specification, appended claims, and/or drawing figures which may be considered new, inventive and industrially applicable.

Copyright may be owned by the Applicant(s) or their assignee and, with respect to express Licensees to third parties of the rights defined in one or more claims herein, no implied license is granted herein to use the invention as defined in the remaining claims. Further, vis-à-vis the public or third parties, no express or implied license is granted to prepare derivative works based on this patent specification, inclusive of the appendix hereto and any computer program comprised therein.

Additional features and functionality of the invention are described in the claims appended hereto. Such claims are hereby incorporated in their entirety by reference thereto in this specification and should be considered as part of the application as filed.

Multiple variations and modifications are possible in the embodiments of the invention described here. Although certain illustrative embodiments of the invention have been shown and described here, a wide range of changes, modifications, and substitutions is contemplated in the foregoing disclosure. While the above description contains many specific details, these should not be construed as limitations on the scope of the invention, but rather exemplify one or another preferred embodiment thereof. In some instances, some features of the present invention may be employed without a corresponding use of the other features. Accordingly, it is appropriate that the foregoing description be construed broadly and understood as being illustrative only, the spirit and scope of the invention being limited only by the claims which ultimately issue in this application.

### Addendum

The following US patent documents, foreign patent documents, and additional publications are incorporated herein by reference thereto, as if fully set forth herein, and relied upon:

US patent documents
U.S. Pat. No. 9,899,223 B2 February 2018 Wimplinger et al.

### Additional Publications

www.ccrtechnology.de/products.php
www.schaeffler.com
www.rollvis.com
www.harmonicdrive.net
U. Gösele et al., “Self-propagating room-temperature silicon wafer bonding in ultrahigh vacuum”, Applied Physics Letters 67, 3614-3616 (1995)
Q.-Y. Tong et al., “Hydrophobic silicon wafer bonding”, Applied Physics Letters 64, 625-627 (1994)
P. Gupta et al., “Hydrogen desorption kinetics from monohydride and dihydride species on silicon surfaces”, Physical Review B 37, 8234-8243 (1988)
T. Suga et al., “Structure of Al—Al and Al—Si₃N₄ interfaces bonded at room temperature by means of the surface activation method”, Acta metall. mater. 40, S133-S137 (1992)
H. Takagi et al., “Surface activated bonding of silicon wafers at room temperature”, Applied Physics Letters 68, 2222-2224 (1996)
C. Flötgen et al., “Novel Surface Preparation Methods for Covalent and Conductive Bonded Interfaces Fabrication”, ECS Transactions 64, 103-110 (2014)
A. Jung et al., “Electrical properties of Si—Si interfaces obtained by room temperature covalent wafer bonding”, Journal of Applied Physics 123, 085701 (2018)
A. Pusel et al., “Photochemical hydrogen desorption from H-terminated silicon (111) by VUV photons”, Physical Review Letters 81, 645-648 (1998)
T. Fujino et al., “Hydrogen segregation and its detrimental effect in epitaxial growth of Ge thin film on hydrogen-terminated Si(001) surface”, Japanese Journal of Applied Physics 40, L1173-L1175 (2001)
M. Tomitori et al,, “STM study of the Ge growth mode on Si(001) substrates”, Applied Surface Science 76/77, 322-328 (1994)
D. Dick et al., “Digermane deposition on Si(100) and Ge(100): from adsorption mechanism to epitaxial growth”, Journal of Physical Chemistry C 118, 482-493 (2014)
P. A. M. van der Heide et al., “Etching of thin SiO₂ layers using wet HF gas”, Journal of Vacuum Science and Technology A 7, 1719-1723 (1989)
H. Takagi et al., in ECS Transactions 75, 3 (2016)
A. Reznicek et al. in MRS Symp. Proc. 681E, I4.4.1 (2001)
T. Suga et al. in IEEE 2001 Electronic Components and Technology Conference
T. Akatsu et al. in J. Mater. Sci. 39, 3031 (2004)
S. Ke et al. in J. Phys. Appl. Phys. 51, 265306 (2018)

1. A production system for oxide-free, covalent semiconductor wafer bonding, the system comprising:
a) a wafer handling chamber with a robot serving at least one load-lock and at least one module for wet chemical or vapor processing of wafers in a substantially atmospheric pressure part of the bonding system at or near atmospheric pressure selected from a list of modules, comprising
i) a module comprising solvent baths for wafer degreasing,
ii) a module with acid baths,
iii) modules for the SC1 and for the SC2 RCA cleaning processes,
iv) a module for oxide removal and surface passivation of wafers by a dilute hydrofluoric acid (HF) solution,
v) a module for oxide removal and surface passivation of wafers by gaseous HF,
vi) a module for deionized water rinsing and spin drying,
b) a wafer handling chamber with a robot serving at least one load-lock and at least one module for ultra-high vacuum wafer processing in a UHV part of the bonding system including at least one chamber selected from at least one of a list of chambers consisting of:
i) a plasma processing chamber with a low energy plasma source suitable for the removal of a surface passivation,
ii) an ultrahigh vacuum laser chamber with a visible or ultraviolet laser suitable for the photochemical or photo-thermal removal of a surface passivation layer,
iii) an ultrahigh vacuum thin film deposition chamber suitable for the provision of a thin, clean epitaxial surface layer,
iv) an ultrahigh vacuum wafer flipping chamber
v) an ultrahigh vacuum wafer annealing chamber,
vi) an ultrahigh vacuum wafer pre-alignment tool, and
vii) an ultrahigh vacuum wafer bonding chamber, wherein the modules for wet chemical processing are accessible through the load-locks and the modules for ultra-high vacuum processing are accessible through the load-locks, and wherein said modules communicate through at least one buffer chamber designed to avoid cross contamination during wafer transfer from the modules for wet chemical to the modules for ultra-high vacuum processing.

2. The system of claim 1, wherein the plasma processing chamber is further equipped with a module, comprising at least one tool from a list of tools, comprising
a) a heater adapted for radiative heating from the back of a wafer with peripheral and bottom heat shields,
b) a rotation mechanism of the cradle on which the wafer rests,
c) a tilt mechanism of the cradle on which the wafer rests, and
d) a mechanism for lifting the wafer above the peripheral heat shield to permit the wafer to be picked up by robot.

3. The system of claim 1, wherein the plasma processing chamber is further equipped with a laser module adapted for local surface heating of wafer and at least one temperature sensor mounted on a tilt module adapted for measuring the local surface temperature at any radial distance between the center and the edge of the wafer and adapted for providing feedback to the rotation speed of wafer and continuous power modulation for the different beam sectors integrated into the laser module for real time control of the surface temperature at any location on wafer.

4. The system of claim 1, wherein the ultrahigh vacuum laser chamber is further equipped with at least one tool selected from at least one of the list of tools consisting of:
a) a rotatable wafer stage,
b) an auxiliary heater for uniform heating of the back of a wafer,
c) an infrared temperature sensor mounted on a tilt module, and
d) a feedback loop between the sensor and the wafer stage and laser power for real time control of the wafer surface temperature.

5. The system of claim 1, wherein the ultrahigh vacuum thin film deposition chamber comprises at least one tool from a list of tools, comprising
a) a rotatable substrate heater,
b) gas lines and a low energy plasma source for plasma assisted CVD, and
c) at least one evaporator for thin film deposition in UHV.

6. The system of claim 1, wherein the ultrahigh vacuum wafer bonding chamber is further equipped with at least one tool from a list of tools, comprising
a) an upper chuck module and a bottom chuck module,
b) a central actuator on a rigid plate the top of the bonding chamber,
c) at least three actuators symmetrically disposed on the rigid plate,
d) a translational stage below the bottom chuck module with a central rotation axis,
e) placement pins for wafer picking and placing on upper and lower chuck module,
f) a set of at least three confocal interferometric sensors adapted to keep the top chuck module horizontal during its approach to the bottom chuck module,
g) a set of at least three confocal interferometric sensors adapted to keep the top chuck module parallel to the bottom chuck module, and
h) a set of at least two confocal interferometric sensors mounted on rotatable and translatable actuators positioned on opposite extremes of the chuck modules with upwards focused beams accurately aligned with downwards focused beams on a vertical axis perpendicular to a wafer plane.

7. The system of claim 6, wherein the bonding chamber has bonding chamber walls adapted for temperature control at a temperature within a range of temperatures, comprising 0.5°-1° C. and 0.05°-0.1° C. by heating cartridges controlled by temperature sensors.

8. The system of claim 1, wherein the modules containing acid baths, the modules for the RCA cleaning processes, and the modules for oxide removal by HF, are all equipped with corrosion resistant gate valves.

9. The system of claim 1, wherein the ultrahigh vacuum bonding chamber is vibrationally decoupled from the handling chamber by an anti-vibrational bellows.

10. A method for oxide-free, covalent semiconductor wafer bonding, the method comprising steps selected at least one of the list of steps, consisting of
a) loading wafers into a load-lock,
b) transporting wafers by a robot of a wafer handling chamber into modules of an atmospheric pressure part of a bonding system,
c) processing wafers in the modules in processing steps selected from one of the list of processing steps consisting of:
i) degreasing wafers in a solvent module,
ii) cleaning wafers in an acid module,
iii) cleaning wafers in RCA cleaning steps in a module for SC1 and a module for SC2,
iv) removing the surface oxide and surface passivation by a dilute HF solution in a module,
v) removing the surface oxide and surface passivation by gaseous HF in a module, and
vi) deionized water rinsing and spin-drying in a module
d) transferring wafers to a buffer chamber attached to a wafer handler of a UHV part with a robot of a bonding system,
e) processing wafers in a process from one of the list of processes consisting of
i) removing the surface passivation by a low energy plasma in a processing chamber,
ii) removing the surface passivation in a photochemical or photo-thermal process with a visible or ultraviolet laser in an ultrahigh vacuum laser chamber,
iii) forming a thin, clean epitaxial surface layer in an ultrahigh vacuum thin film deposition chamber,
iv) flipping a wafer in an ultrahigh vacuum wafer flipping chamber,
v) annealing a wafer in an ultrahigh vacuum wafer annealing chamber,
vi) pre-align a wafer in an ultrahigh vacuum wafer pre-alignment tool, and
vii) covalently bonding wafers in an ultrahigh vacuum wafer bonding chamber.

11. The method of claim 10, wherein removing the surface passivation by a low energy plasma in a processing chamber is assisted by steps selected from at least one of the list of steps consisting of:
a) rotating a wafer,
b) radiatively heating a wafer by a heater from the back of the wafer, and
c) heating a surface of a wafer by a visible or UV laser module comprising different beam sectors and controlling a local surface temperature of the wafer by a feedback loop between a temperature sensor mounted on a tilt module, the rotation speed and the power supplied to the different beam sectors.

12. The method of claim 10, wherein removing the surface passivation by a visible or ultraviolet laser in an ultrahigh vacuum laser chamber is assisted by steps selected from one of the list of steps consisting of:
a) rotating a wafer,
b) uniformly heating a wafer by a heater from the back of the wafer, and
c) controlling a surface temperature of a wafer during laser heating by a feedback loop between a temperature sensor mounted on a tilt module, the rotation speed and the power supplied to the laser.

13. The method of claim 10, wherein forming the thin, clean epitaxial surface layer comprises steps selected from at least one of the list of steps consisting of:
a) rotating the substrate during forming the thin surface layer,
b) heating the substrate during forming the thin surface layer,
c) providing a low-energy plasma source, gas lines and mass flow controllers for plasma assisted chemical vapor deposition for forming the thin surface layer, and
d) forming the thin surface layer from an evaporator selected from at least one of the list of evaporators consisting of
i) electron beam evaporators, and
ii) effusion cells.

14. The method of claim 10, wherein covalently bonding wafers in an ultrahigh vacuum wafer bonding chamber comprises steps from at least one of the list of steps consisting of:
a) transferring a first wafer to an upper chuck module,
b) transferring a second wafer to a bottom chuck module,
c) lowering the upper chuck module towards the lower chuck module to a distance of less than 20 mm, while preserving parallelism between lower and upper chuck module by confocal interferometric sensors,
d) moving confocal interferometric sensors into measurement positions between first and second wafer by activating rotatable and translatable actuators,
e) finding and imaging alignment marks on opposite extremes on the first wafer by the upwards focused beams while scanning the confocal interferometric sensors in x-y direction by actuating the actuators,
f) positioning the upwards focused beams of sensors exactly into the center of the alignment features by actuating the actuators,
g) keeping the actuators with sensors fixed,
h) actuating the rotation of the bottom chuck module to find alignment features on the second wafer by the downward focused beams of the confocal interferometric sensors by rotational scanning in clockwise and anti-clockwise directions, whereby generating an image of the trench profile to identify the positions of the deeper trenches,
i) aligning the trenches of alignment features on the second wafer parallel to the trenches of the alignment features on the first wafer by activating the rotation,
j) keeping the rotation actuator fixed,
k) bringing the downwards focused beams exactly into the center of the alignment features on the second wafer by moving the translational stage in x-y direction, thereby bringing the centers of the alignment features on the first wafer and the centers of the alignment features on the second wafer into exact coincidence,
l) rotating the sensors to a home position outside the chuck modules,
m) lowering the upper chuck module towards the lower chuck module to a distance of about 100-200 μm, while preserving parallelism between lower and upper chuck modules by confocal interferometric sensors,
n) establishing a first contact between the wafers by activating a pushing action by a central actuator, and
o) exerting pressure by actuating symmetrically disposed actuators under torque control.
